(19) United States
(12) Patent Application Publication
(10) Pub. No.: US 2026/0047156 A1
(43) Pub. Date: Feb. 12, 2026

(54) GATE-ALL-AROUND TRANSISTORS WITH REDUCED PARASITIC CAPACITANCE

(71) Applicant: Taiwan Semiconductor Manufacturing Company, Ltd., Hsin-Chu (TW)

(72) Inventors: Ta-Chun Lin, Hsinchu (TW); Pin Chun Shen, Changhua County (TW); Chih-Hao Chang, Hsinchu (TW); Jhon Jhy Liaw, Hsinchu County (TW)

(21) Appl. No.: 18/798,094

(22) Filed: Aug. 8, 2024

(51) Int. Cl. H01L 29/06; H01L 21/02; H01L 29/423; H01L 29/66; H01L 29/775; H01L 29/786

(52) U.S. Cl. CPC H10D 62/116; H01L 21/02617; H10D 62/124; H10D 64/017; H10D 64/018; H10D 30/014; H10D 30/43; H10D 30/6735; H10D 30/6757; H10D 62/121

(57) ABSTRACT

A semiconductor structure and a method of forming the same are provided. In an embodiment, an exemplary method includes forming a source/drain opening extending through of a fin-shaped active region that comprises a plurality of channel layers interleaved by a plurality of sacrificial layers, replacing the plurality of sacrificial layers with a plurality of dielectric layers, recessing the plurality of dielectric layers to form inner spacer recesses, forming inner spacer features in the inner spacer recesses, where a bottommost inner spacer feature of the inner spacer features is thicker than one inner spacer feature of the inner spacer features disposed over the bottommost inner spacer feature, forming an isolation layer in the source/drain opening, and forming a source/drain feature in the source/drain opening and over the isolation layer, wherein the source/drain feature is spaced apart from the isolation layer by an air gap.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate devices are introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. The channel region of a GAA transistor may be formed from nanowires, nanosheets, other nanostructures, and/or other suitable structures. The shapes of the channel region have also given a GAA transistor alternative names such as a nanostructure transistor, a nanosheet transistor, or a nanowire transistor. As integrated circuit (IC) technologies progress towards smaller technology nodes, parasitic capacitance of dielectric components disposed between active device regions may have serious bearings on the overall performance of an IC device. In some examples, high parasitic capacitance may lead to lower device speed (e.g., RC delays) when separation distances between the active device regions reduces to meet design requirements of smaller technology nodes. While methods of reducing parasitic capacitance in (GAA) transistors have been generally adequate for their intended purposes, they have not been entirely satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for forming a semiconductor structure, according to one or more aspects of the present disclosure.

FIGS. 2, 3, 4, 5, 6, 7, 8, 9, 10, 11, 12 and 13 illustrate fragmentary cross-sectional views of the semiconductor structure during various fabrication stages in the method of FIG. 1, according to one or more aspects of the present disclosure.

FIG. 14 illustrates a flow chart of a method for forming a first alternative semiconductor structure, according to one or more aspects of the present disclosure.

FIGS. 15, 16, 17, 18, 19, 20, 21, 22, 23 and 24 illustrate fragmentary cross-sectional views of the first alternative semiconductor structure during various fabrication stages in the method of FIG. 14, according to one or more aspects of the present disclosure.

FIG. 25 illustrates a flow chart of a method for forming a second alternative semiconductor structure, according to one or more aspects of the present disclosure.

FIGS. 26, 27, 28, 29, 30, 31, 32, 33, 34 and 35 illustrate fragmentary cross-sectional views of the second alternative semiconductor structure during various fabrication stages in the method of FIG. 25, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

The present disclosure provides methods of reducing parasitic capacitance in field-effect transistors (FETs) including multi-gate FETs such as gate-all-around (GAA) FETs. Some embodiments provide methods of lowering parasitic capacitance by forming a void (e.g., an air gap) between source/drain feature and substrate. In an embodiment, a method of forming a GAA transistor of the present disclosure includes forming inner spacer features with different heights (or “thickness”). For example, a bottommost inner spacer features of the inner spacer features is configured to have a height greater than a height of a topmost inner spacer feature of the inner spacer features. By forming the GAA transistor having a void disposed under the source/drain feature, parasitic capacitance associated with the source/drain feature and the metal gate structure adjacent to the source/drain feature may be reduced to improve device performance.

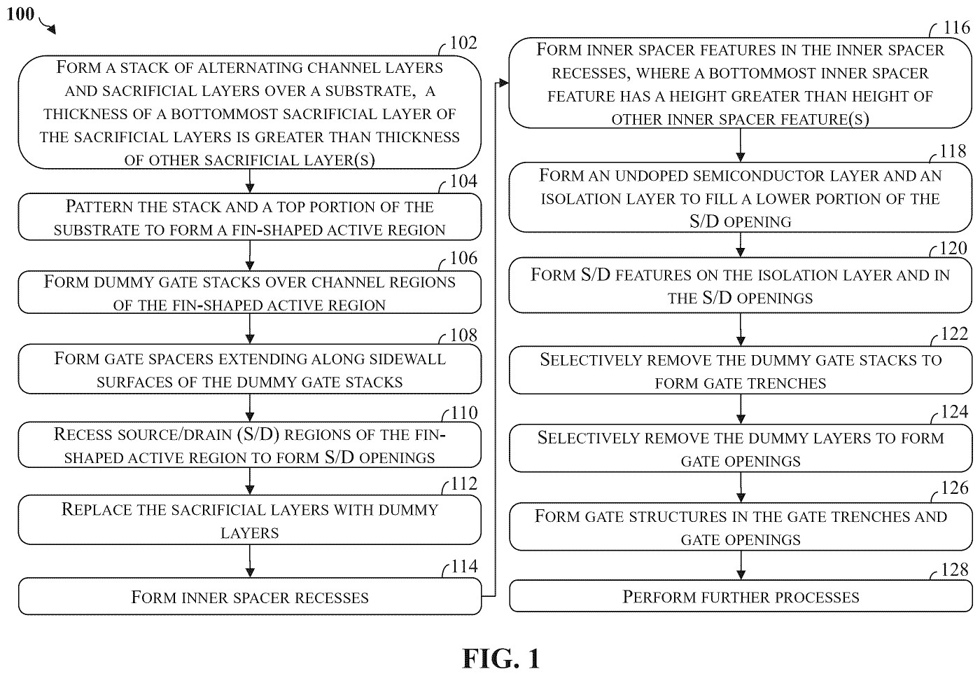

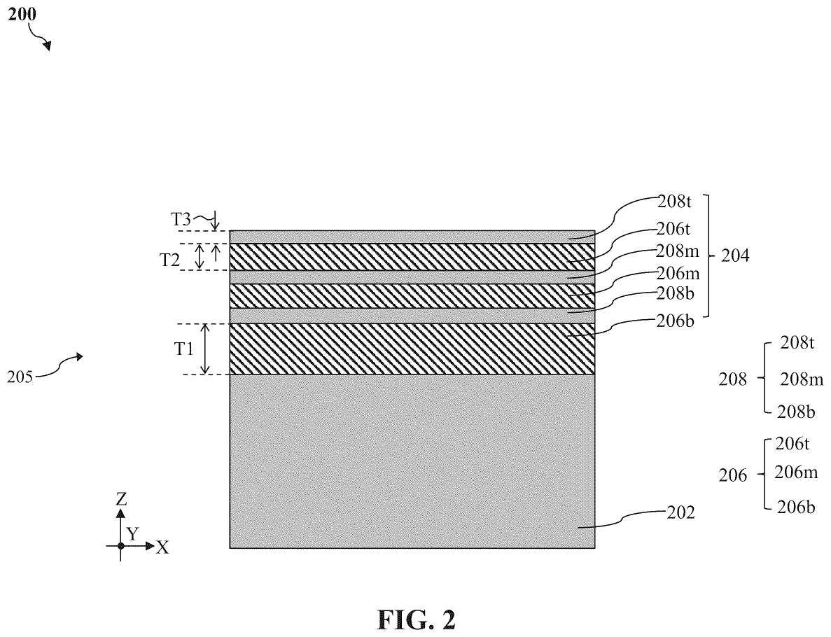

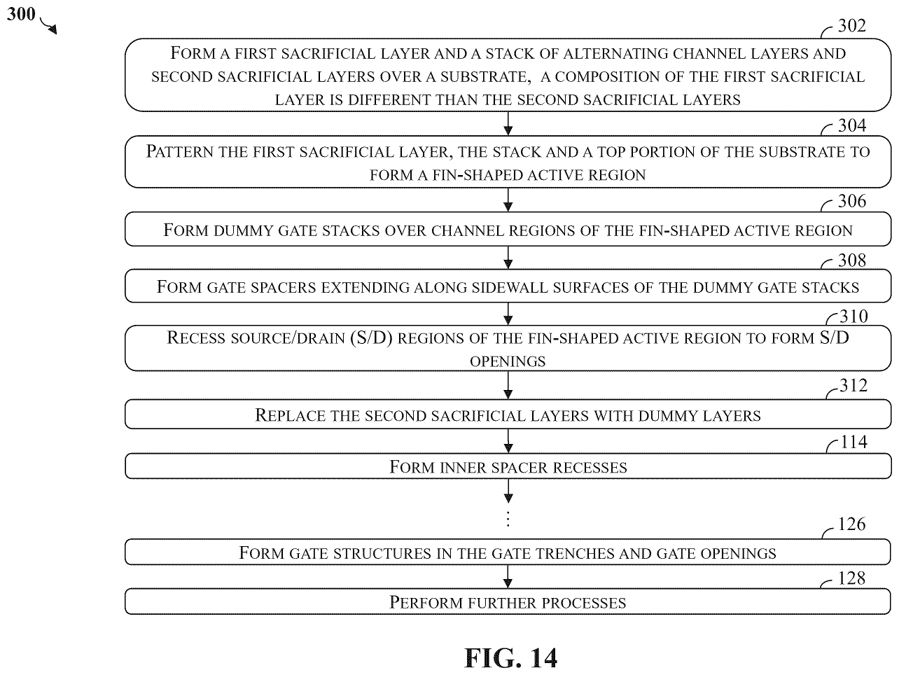

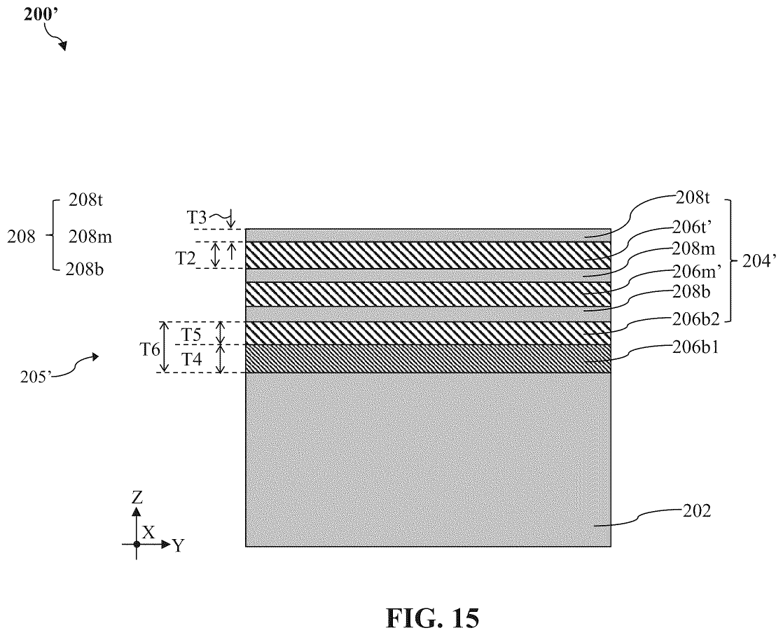

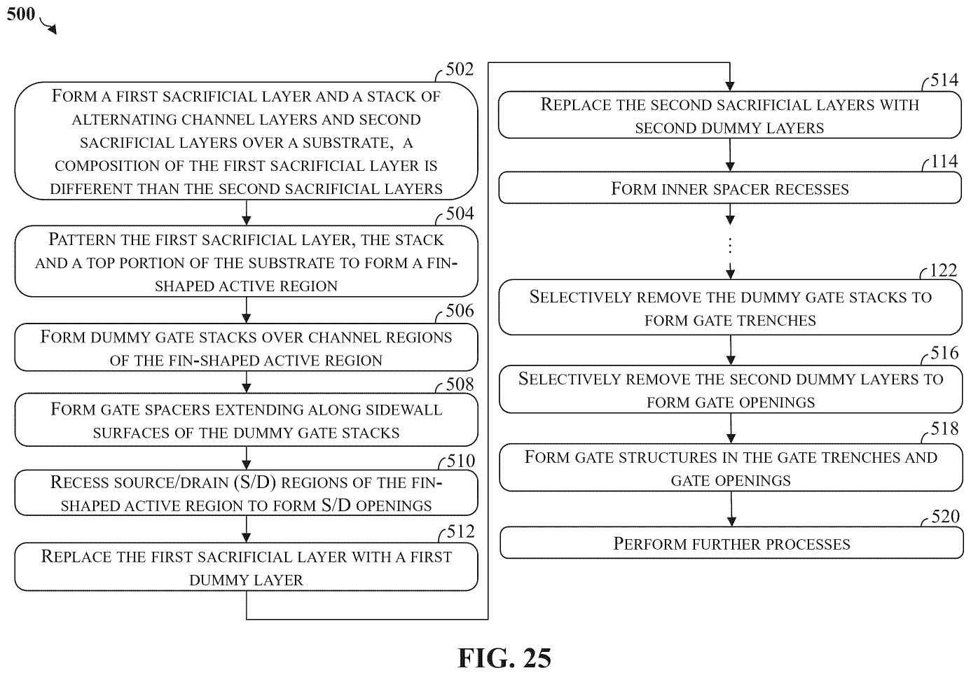

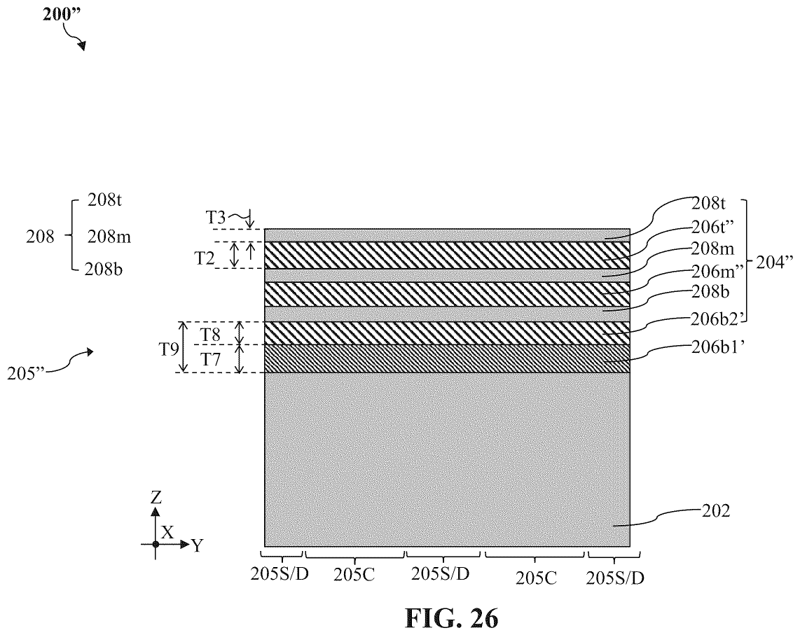

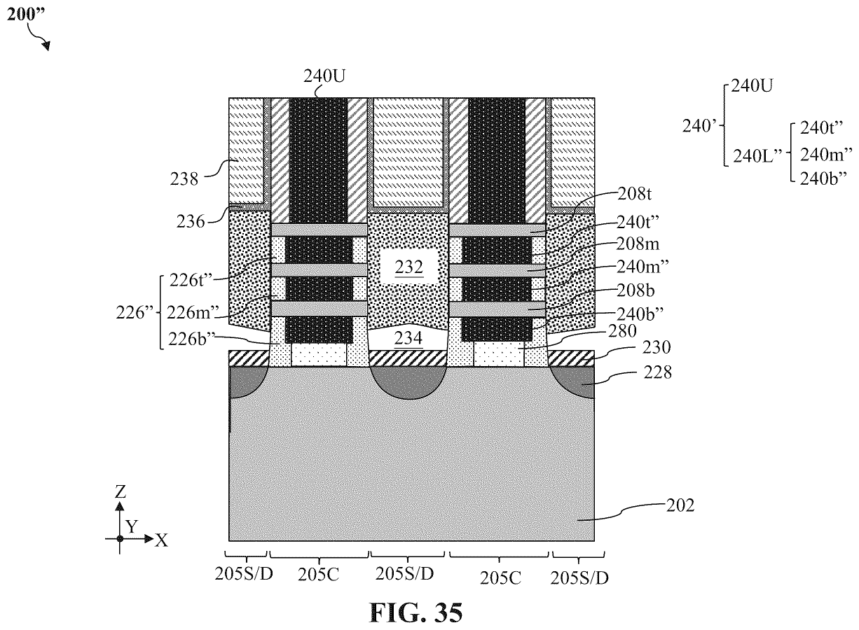

The various aspects of the present disclosure will now be described in more detail with reference to the figures. In that regard, FIG. 1 is a flowchart illustrating method 100 of forming a semiconductor structure 200 according to embodiments of the present disclosure. Method 100 is described below in conjunction with FIGS. 2-13. FIG. 14 is a flowchart illustrating method 300 of forming a semiconductor structure 200′ according to embodiments of the present disclosure. Method 300 is described below in conjunction with FIGS. 15-24. FIG. 25 is a flowchart illustrating method 500 of forming a semiconductor structure 200″ according to embodiments of the present disclosure. Method 500 is described below in conjunction with FIGS. 26-35. Each of the methods 100, 300, 500 is merely an example and is not intended to limit the present disclosure to what is explicitly illustrated therein. Additional steps may be provided before, during, and/or after the method, and some steps described can be replaced, eliminated, or moved around for additional embodiments of the method. Not all steps are described herein in detail for reasons of simplicity. For avoidance of doubts, the X, Y and Z directions in FIGS. 2-13, 15-24, 26-35 are perpendicular to one another and are used consistently. Throughout the present disclosure, like reference numerals denote like features unless otherwise excepted.

Referring to FIGS. 1 and 2, method 100 includes a block 102 where a stack 204 of alternating channel layers and sacrificial layers are formed over a substrate 202. In one embodiment, the substrate 202 is a silicon (Si) substrate. In some other embodiments, the substrate 202 may include other semiconductors such as germanium (Ge), silicon germanium (SiGe), or a III-V semiconductor material. Exemplary III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 202 may also include an insulating layer, such as a silicon oxide layer, to have a semiconductor-on-insulator (SOI) structure. Although not explicitly shown in the figures, the substrate 202 may include an n-type well region and a p-type well region for fabrication of transistors of different conductivity types. When present, each of the n-type well and the p-type well is formed in the substrate 202 and includes a doping profile. An n-type well may include a doping profile of an n-type dopant, such as phosphorus (P) or arsenic (As). A p-type well may include a doping profile of a p-type dopant, such as boron (B). The doping in the n-type well and the p-type well may be formed using ion implantation or thermal diffusion and may be considered portions of the substrate 202.

As shown in FIG. 2, the stack 204 includes a number of sacrificial layers (e.g., 206b, 206m, 206t) and a number of channel layers (e.g., 208b, 208m, 208t) interleaved by the number of sacrificial layers. The sacrificial layers 206b, 206m, 206t may be collectively or individually referred to as the sacrificial layers 206 or the sacrificial layer 206; and the channel layers 208b, 208m, 208t may be collectively or individually referred to as the channel layers 208 or the channel layer 208. The channel layers 208 and the sacrificial layers 206 include different materials to provide etch selectivity. Each channel layer 208 may include a semiconductor material such as, for example, Si, Ge, SiC, SiGe, GeSn, SiGeSn, SiGeCSn, other suitable semiconductor materials, or combinations thereof, while each sacrificial layer 206 has a material different from that of the channel layer 208. In one such example, the channel layers 208 may include elemental Si and the sacrificial layers 206 may include SiGe. Constituent atomic percentages of the sacrificial layers 206 may be substantially the same. For example, the sacrificial layers 206 each may include the same germanium concentration.

In the present embodiments, to facilitate the formation of voids (or air gaps) to reduce parasitic capacitance (e.g., fringe capacitance) between metal gate structure and its adjacent source/drain features, the bottommost sacrificial layer 206b is configured to have a thickness T1 greater than a thickness of other sacrificial layers (e.g., 206m, 206t). For example, the topmost sacrificial layer 206t has a thickness T2, and a ratio of the thickness T1 to the thickness T2 is in a range between about 1.1 and about 3. If the ratio is greater than about 3, the space for forming metal gate structure under the bottommost channel layer 208b may be much bigger than the space for forming metal gate structure between the channel layer 208t and the channel layer 208m, leading to unwanted threshold voltage variations; if the ratio is less than about 1.1, the thickness difference between the sacrificial layers 206 may be too small to form a void (e.g., air gap), or the volume of the void (e.g., air gap) may be too small to effectively reduce the parasitic capacitance. For the same reasons, a ratio of the thickness T1 to a thickness of the middle sacrificial layer 206m is in a range between about 1.1 and about 3. In an embodiment, the thickness T2 of the topmost sacrificial layer 206t is substantially equal to the thickness of the middle sacrificial layer 206m. In various embodiments, the channel layers 208 each have the same thickness T3, and the thickness T1 and the thickness T2 may be greater than the thickness T3.

The sacrificial layers 206 and channel layers 208 may be deposited using an epitaxial process. Suitable epitaxial processes include vapor-phase epitaxy (VPE), ultra-high vacuum chemical vapor deposition (UHV-CVD), molecular beam epitaxy (MBE), and/or other suitable processes. As shown in FIG. 2, the sacrificial layers 206 and the channel layers 208 are deposited alternatingly, one-after-another, to form the stack 204. It is noted that three layers of the sacrificial layers 206 and three layers of the channel layers 208 are alternately and vertically arranged as illustrated in FIG. 2, which are for illustrative purposes only and not intended to be limiting beyond what is specifically recited in the claims. It is understood that any number of sacrificial layers and channel layers can be formed in the stack 204. The number of layers depends on the desired number of channels members for the device 200. In some embodiments, the number of the channel layers 208 is between 2 and 10, and the number of the sacrificial layers 206 is between 2 and 10.

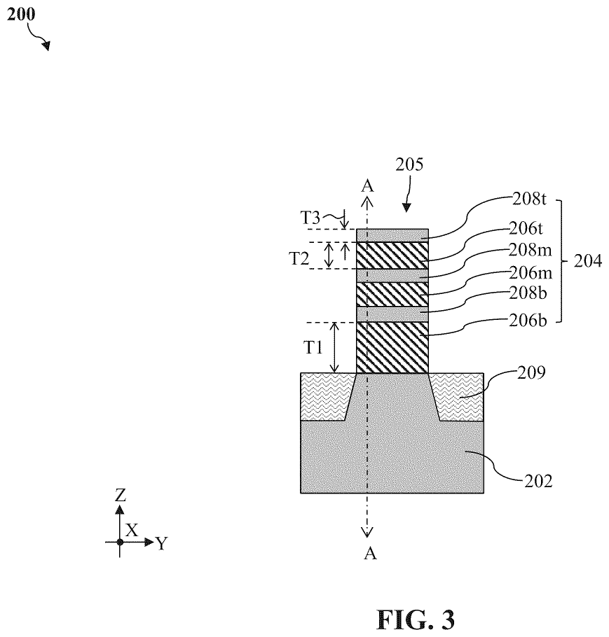

Referring to FIGS. 1 and 2-3, method 100 includes a block 104 where the stack 204 and a top portion of the substrate 202 are patterned to form a fin-shaped active region 205. FIG. 2 depicts a fragmentary cross-sectional view of the structure 200 taken along line A-A as shown in FIG. 3. To pattern the stack 204, a hard mask layer may be deposited over the stack 204 to form an etch mask. The hard mask layer may be a single layer or a multi-layer. For example, the hard mask layer may include a pad oxide layer and a pad nitride layer disposed over the pad oxide layer. The fin-shaped active region 205 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. In some implementations, double-patterning or multi-patterning processes may be used to define fin-shaped active regions that have, for example, pitches smaller than what is otherwise obtainable using a single, direct photolithography process. As shown in FIG. 3, the fin-shaped active region 205 that includes the sacrificial layers 206 and the channel layers 208 extends vertically along the Z direction and lengthwise along the X direction.

After forming the fin-shaped active region 205, an isolation feature 209 (shown in FIG. 3) is formed adjacent to and around the lower portion of the fin-shaped active region 205. The isolation feature 209 is disposed between the fin-shaped active region 205 and another fin-shaped active region 205. The isolation feature 209 may also be referred to as a shallow trench isolation (STI) feature 209. In some embodiments, the isolation feature 209 may include silicon oxide, silicon nitride, silicon oxynitride, fluorine-doped silicate glass (FSG), a low-k dielectric, combinations thereof, and/or other suitable materials. The formation of the isolation feature 209 may involve multiple processes such as deposition and etching. As shown in FIG. 3, the fin-shaped active region 205 rises above the isolation feature 209.

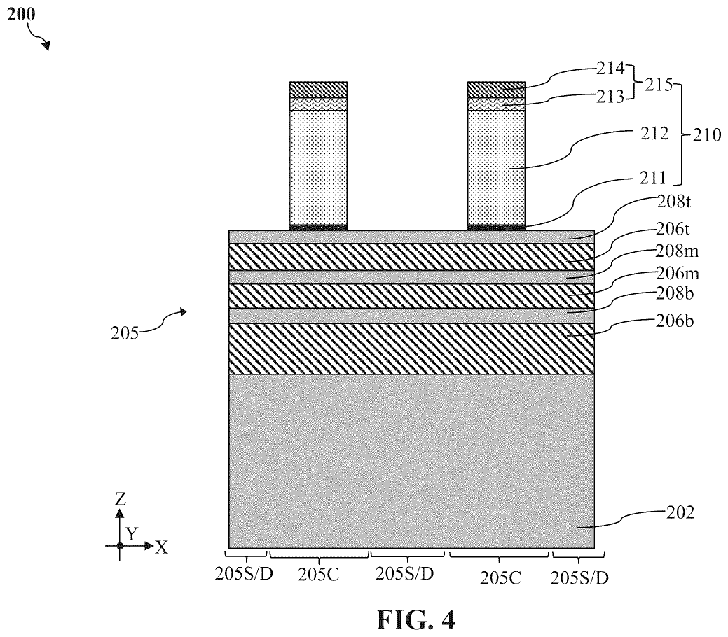

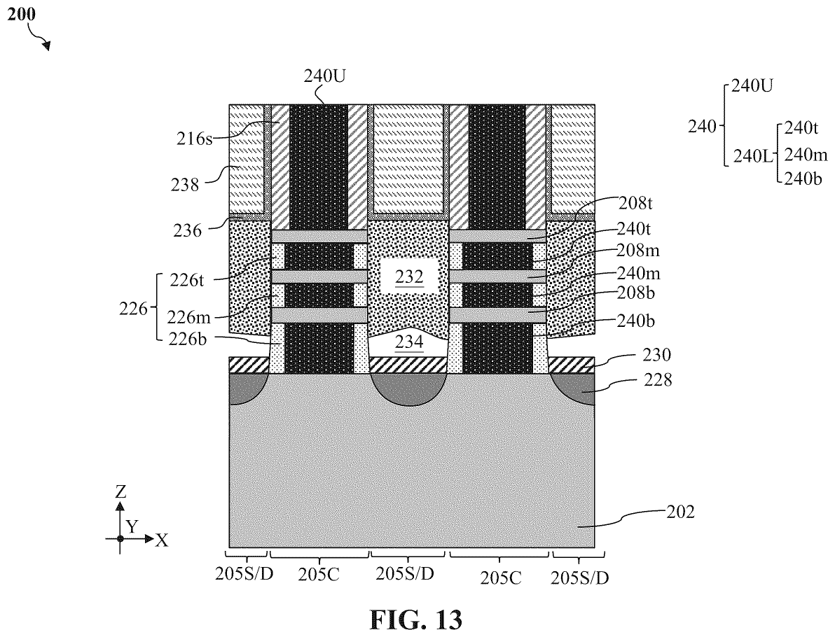

Referring to FIGS. 1 and 4, method 100 includes a block 106 where dummy gate stacks 210 are formed over channel regions 205C of the fin-shaped active region 205. The channel regions 205C and the dummy gate stacks 210 also define source/drain regions 205S/D that are not vertically overlapped by the dummy gate stacks 210. Each of the channel regions 205C is disposed between two source/drain regions 205S/D along the X direction. Two dummy gate stacks 210 are shown in FIG. 4 but the structure 200 may include more dummy gate stacks 210. The dummy gate stack 210 includes a dummy dielectric layer 211, a dummy gate electrode layer 212 over the dummy dielectric layer 211, and a gate-top hard mask layer 215 over the dummy gate electrode layer 212. The dummy dielectric layer 211 may include silicon oxide. The dummy gate electrode layer 212 may include polysilicon. The gate-top hard mask layer 215 may be a multi-layer that includes a silicon oxide layer 213 and silicon nitride layer 214 formed on the silicon oxide layer 213. Suitable deposition process, photolithography and etching process may be employed to form the dummy gate stack 210. In this embodiment, a gate replacement process (or gate-last process) is adopted where the dummy gate stacks 210 serve as placeholders for functional gate structures 240 (shown in FIG. 13). Other processes and configuration are possible.

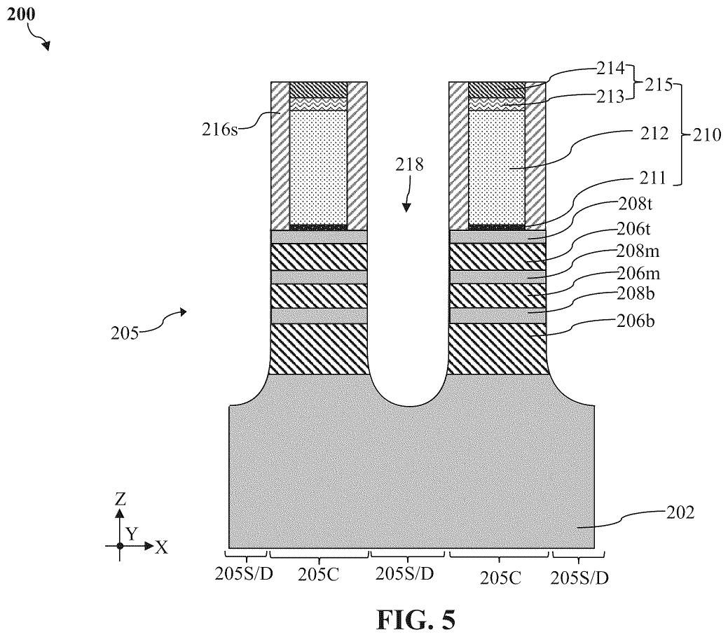

Referring to FIGS. 1 and 5, method 100 includes a block 108 where gate spacers 216s are formed to extend along sidewall surfaces of the dummy gate stacks 210. In an example process, the formation of the gate spacers 216s includes conformally depositing a single-layer or a multi-layer dielectric layer (not shown) over the structure 200 and etching back of the dielectric layer from top-facing surfaces of the structure 200 by an anisotropic etch process. The dielectric layer is deposited using chemical vapor deposition (CVD), atomic layer deposition (ALD), or sub-atmospheric chemical vaper deposition (SACVD), and may include silicon oxide, silicon nitride, silicon carbide, silicon oxynitride, silicon carbonitride, silicon oxycarbide, silicon oxycarbonitride, and/or combinations thereof. The term “conformally” may be used herein for case of description of a layer having a substantially uniform thickness over various regions. The profile of the gate spacer 216s shown in FIG. 5 is just an example and is not intended to be limiting. For example, in some embodiments, the gate spacer 216s may have a non-uniform width from bottom to top, and a top surface of the gate spacer 216s may be lower than a top surface of the dummy gate stack 210.

Still referring to FIGS. 1 and 5, method 100 includes a block 110 where source/drain regions 205S/D of the fin-shaped active region 205 are recessed to form source/drain openings 218. In some embodiments, the source/drain regions 205S/D of the fin-shaped active region 205 that are not covered by the dummy gate stacks 210 and the gate spacers 216s are anisotropically etched by a dry etch or a suitable etching process to form source/drain openings 218. An exemplary dry etching process may implement an oxygen-containing gas, hydrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. The source/drain openings 218 extend through the stack 204 of channel layers 208 and sacrificial layers 206 and partially extend into the substrate 202. As illustrated by FIG. 5, sidewalls of the channel layers 208 and the sacrificial layers 206 are exposed in the source/drain openings 218.

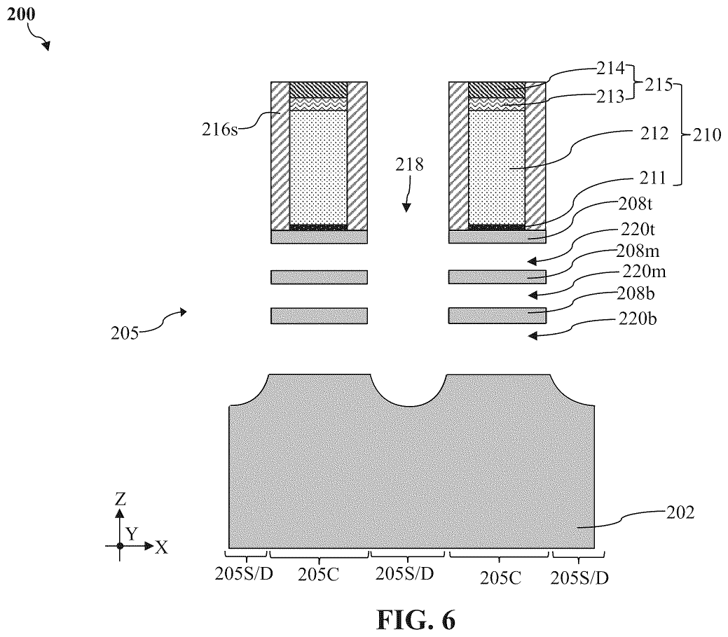

Referring to FIGS. 1 and 6-8, method 100 includes a block 112 where the sacrificial layers 206 are replaced with dummy layers. With reference to FIG. 6, after the formation of the source/drain openings 218, the sacrificial layers 206 interleaving the channel layers 208 in the channel region 205C are selectively removed. The selective removal of the sacrificial layers 206 releases the channel layers 208 to form channel members 208 shown in FIG. 6. Depending on the design, the channel members 208 may take form of nanowires, nanosheets, or other nanostructures. The selective removal of the sacrificial layers 206 forms spaces (e.g., spaces 220t, 220m, 220b) between and around adjacent channel members 208. The bottommost space 220b spans a height greater than the height of the space 220t and the space 220m. For example, a ratio of the height of the bottommost space 220b to the height of the space 220t is in a range between about 1.1 and about 3. In an embodiment, the height of the bottommost space 220b is substantially equal to the thickness T1, and the height of the space 220m and the height of the space 220t are substantially equal to the thickness T2. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

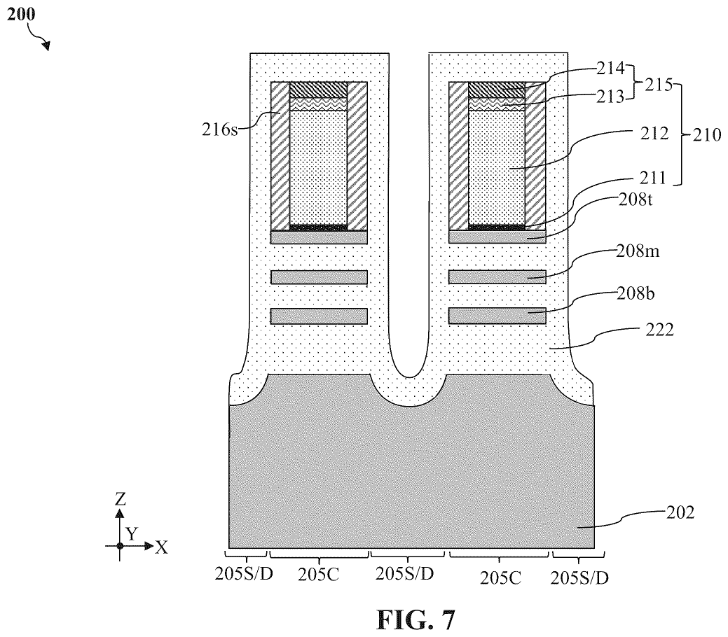

With reference to FIG. 7, after the selective removal of the sacrificial layers 206, a dielectric material layer 222 is deposited around the channel members 208 and over the source/drain openings 218. The dielectric material layer 222 may include silicon oxide, silicon nitride, silicon oxynitride, silicon carbonitride, silicon oxycarbonitride, high-K dielectric materials (e.g., aluminum oxide, hafnium oxide), other suitable materials, or combinations thereof, and may be deposited using plasma enhanced chemical vapor deposition (PECVD) or ALD or other suitable methods. In an embodiment, the dielectric material layer 222 includes silicon oxide. As shown in FIG. 7, the dielectric material layer 222 fills the space (e.g., spaces 220t, 220m, 220b) among the channel members 208 and covers end sidewalls of the channel members 208. Additionally, the dielectric material layer 222 is in direct contact with a sidewall of the gate spacer 216s and a top surface of the substrate 202. In an embodiment, the dielectric material layer 222 extends conformally over the substrate 202.

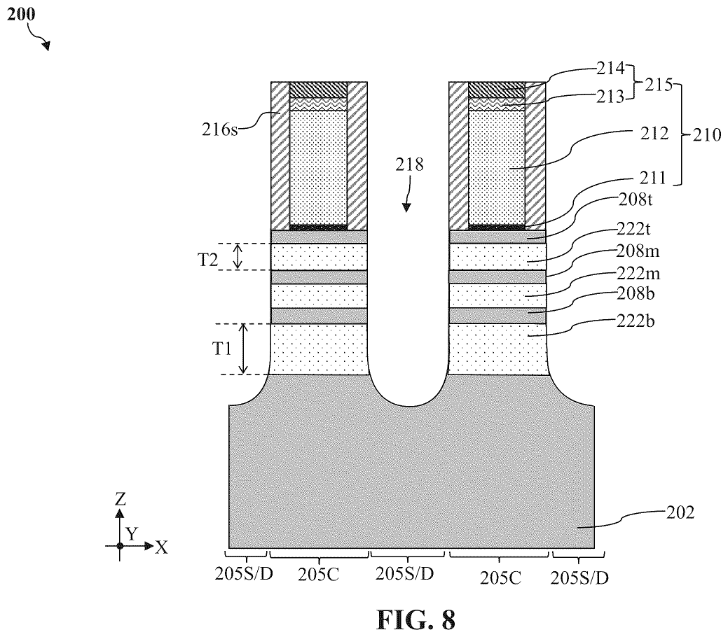

With reference to FIG. 8, after the deposition of the dielectric material layer 222, an etching process is performed to selectively etch the dielectric material layer 222, thereby forming the dummy layers (e.g., dummy layers 222t, 222m, 222b) interleaved by the channel members 208. In the present embodiment, the dummy layers 222t, 222m, 222b have different heights (or thicknesses). For example, a thickness of the bottommost dummy layer 222b is substantially equal to the thickness T1 of the bottommost sacrificial layer 206b, and a thickness of the dummy layer 222t is substantially equal to the thickness T2 of the sacrificial layer 206t. In an embodiment, the thickness of the dummy layer 222m is substantially equal to the thickness of the dummy layer 222t.

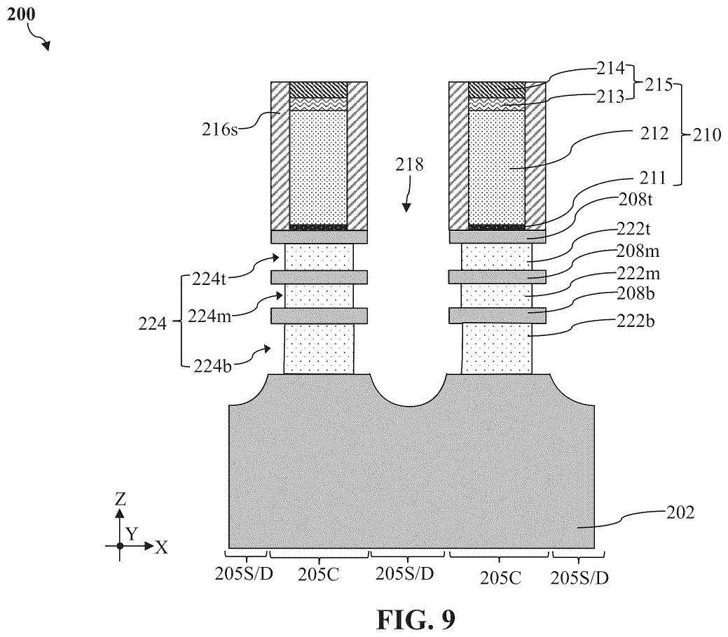

Referring to FIGS. 1 and 9, method 100 includes a block 114 where inner spacer recesses (e.g., inner spacer recesses 224t, 224m, 224b) are formed. After forming the dummy layers 222t, 222m, 222b, an etching process is performed to selectively recess the dummy layers 222t, 222m, 222b to form inner spacer recesses (e.g., inner spacer recesses 224t, 224m, 224b). The etching process selectively and partially recess the dummy layers 222t, 222m, 222b to form inner spacer recesses, while the exposed channel members 208 are not significantly etched. In an embodiment where the channel members 208 consist essentially of silicon (Si) and the dummy layers 222t, 222m, 222b are formed of silicon oxide, the selective recess of the dummy layer 222t, 222m, 222b may be performed using a selective wet etch process or a selective dry etch process. An example selective dry etching process may include use of carbon tetrafluoride (CF₄), nitrogen trifluoride (NF₃), hydrogen (H₂), or a mixture thereof. An example selective wet etching process may include use of hydrofluoric acid, ammonium fluoride, or a mixture thereof. The extent at which the dummy layers 222t, 222m, 222b are recessed is controlled by duration of the etching process. In an alternative embodiment, the etch back of the dielectric material layer 222 and the selective and partial recess of the dummy layers 222t, 222m, 222b are conducted by performing a same etching process. In the present embodiment, the inner spacer recesses 224t, 224m, 224b have different heights. In an embodiment, a ratio of a height of the bottommost inner spacer recess 224b to a height of the topmost inner spacer recess 224t is in a range between about 1.1 and about 3. In an embodiment, a ratio of a height of the bottommost inner spacer recess 224b to a height of the inner spacer recess 224m is in a range between about 1.1 and about 3. For example, the height of the bottommost inner spacer recess 224b is substantially equal to the thickness T1 of the bottommost sacrificial layer 206b, and the height of the inner spacer recess 224t is substantially equal to the thickness T2 of the topmost sacrificial layer 206t. In some embodiments, the height of the inner spacer recess 224m is substantially equal to the height of the inner spacer recess 224t. The inner spacer recesses 224t, 224m, 224b may be collectively or individually referred to as the inner spacer recesses 224.

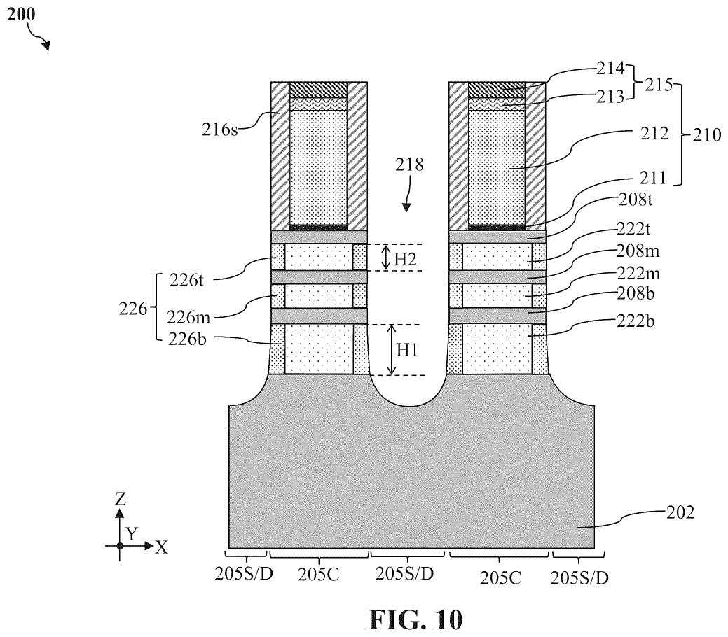

Referring to FIGS. 1 and 10, method 100 includes a block 116 where inner spacer features 226 are formed in the inner spacer recesses 224. After the formation of the inner spacer recesses 224, an inner spacer material layer (not shown) is deposited over the structure 200, including in the inner spacer recesses 224. The inner spacer material layer may include silicon oxide, silicon nitride, silicon oxycarbide, silicon oxycarbonitride, silicon carbonitride, metal nitride, or a suitable dielectric material. The deposited inner spacer material layer is then etched back to remove excessive inner spacer material layer, thereby forming the inner spacer features 226. The etch back process at block 116 may be a dry etching process that is similar to the dry etching process used in the formation of the source/drain openings 218. The inner spacer features 226 track the shapes of the corresponding inner spacer recesses 224. In this illustrated example, the inner spacer features 226 includes a bottommost inner spacer feature 226b formed in the inner spacer recess 224b, a middle inner spacer feature 226m formed in the inner spacer recess 224m, and a topmost inner spacer feature 226t formed in the inner spacer recess 224t. The bottommost inner spacer feature 226b has a height H1, the topmost inner spacer feature 226t has a height H2, and a ratio of the height H1 to the height H2 is in a range between about 1.1 and about 3. If the ratio is greater than about 3, the space for forming metal gate structure adjacent to the bottommost inner spacer feature 226b may be much bigger than the space for forming metal gate structure adjacent to the inner spacer feature 226t, leading to unwanted threshold voltage variations; if the ratio is less than about 1.1, the height difference between the inner spacer features 226 may be too small such that epitaxial layers of source/drain features may merge without forming a void (e.g., air gap), or the volume of the void may be too small to effectively reduce the parasitic capacitance. For the same reasons, a ratio of the height H1 to a height of the middle inner spacer feature 226m is in a range between about 1.1 and about 3. In an embodiment, the height of the middle inner spacer feature 226m is substantially equal to the height H2 of the topmost inner spacer feature 226t. In various embodiments, the channel layers 208 each have the same thickness T3, and the height H1 and the height H2 are greater than the thickness T3.

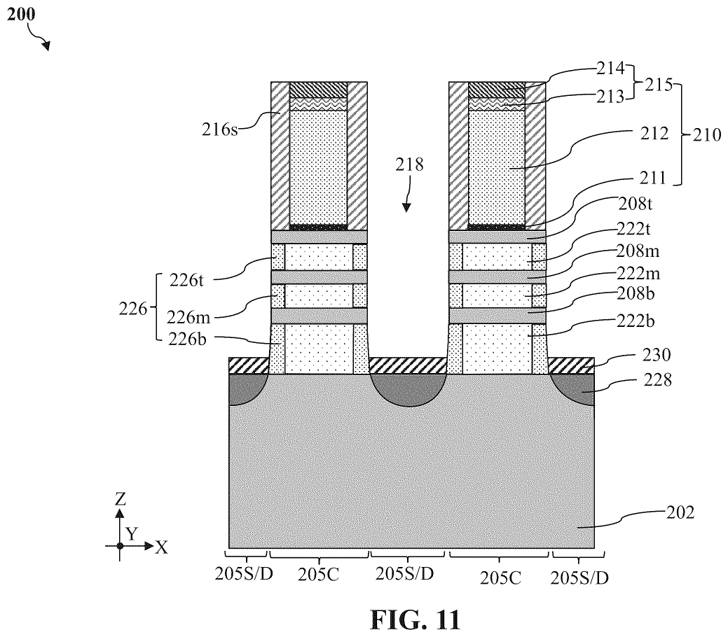

Referring to FIGS. 1 and 11, method 100 includes a block 118 where an undoped semiconductor layer 228 and an isolation layer 230 are formed in the lower portion of the source/drain opening 218. In the present embodiments, after forming the inner spacer features 226, a semiconductor layer 228 is formed over a top surface of the substrate 202 exposed in the source/drain openings 218 by using an epitaxial process. The semiconductor layer 228 may be undoped or not intentionally doped and may include undoped silicon (Si), undoped germanium (Ge), undoped silicon germanium (SiGe), or other suitable materials. In an embodiment, the semiconductor layer 228 includes undoped silicon (Si). After forming the semiconductor layer 228, the isolation layer 230 is formed in the source/drain openings 218 and on the semiconductor layer 228. In an example process, a dielectric layer is deposited over the structure 200 by using a physical vaper deposition (PVD) process. Due to the properties of the PVD process, a portion of the dielectric layer formed on a top or planar surface are thicker than a portion of dielectric layer formed on a side surface. That is, the dielectric layer includes a first portion formed over top surfaces of the dummy gate stacks 210, a second portion extending along exposed sidewall surfaces of the source/drain openings 218 and sidewall surfaces of the gate spacers 216s, and a third portion formed on the exposed top surface of the semiconductor layer 228. A thickness of the first portion and third portion are greater than a thickness of the second portion. Then, a combination of deposition, lithography, and etching processes are performed to remove the first portion and the second portion of the insulation layer, leaving at least a part of the third portion of the dielectric layer in the source/drain openings 218, thereby forming the isolation layer 230 in the source/drain openings 218. The top surface of the isolation layer 230 is below the top surface of the bottommost inner spacer feature 226b to facilitate the formation of void (e.g., air gap). In an embodiment, a thickness of the isolation layer 230 is less than the height H1 of the bottommost inner spacer feature 226b. The isolation layer 230 may include silicon nitride (SiN), silicon oxynitride (SiON), silicon oxycarbonitride (SiOCN), silicon oxycarbide (SiOC), silicon carbonitride (SiCN), aluminum oxide, hafnium oxide, or other suitable materials. In an embodiment, the isolation layer 230 and the inner spacer features 226 have the same composition. In some embodiments, top surfaces of the semiconductor layer 228 and the isolation layer 230 are substantially planar. In some other embodiments, top surfaces of the semiconductor layer 228 and the isolation layer 230 may include concave surfaces or convex surfaces, depending upon the duration of the epitaxial growth process for forming the semiconductor layer 228.

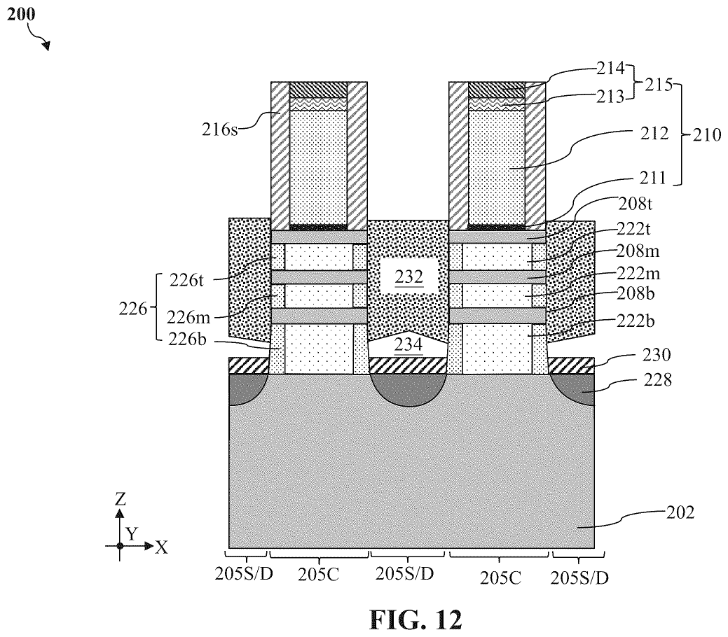

Referring to FIGS. 1 and 12, method 100 includes a block 120 where source/drain features 232 are formed in the source/drain openings 218 and over the isolation layers 230. Source/drain feature(s) may refer to a source or a drain, individually or collectively dependent upon the context. The source/drain features 232 are coupled to the channel members (e.g., channel members 208t, 208m, 208b) of the channel regions 205C and each may be epitaxially and selectively formed from exposed semiconductor surfaces (e.g., sidewalls of the channel members 208t, 208m, 208b) by using an epitaxial process, such as vapor phase epitaxy (VPE), ultrahigh vacuum chemical vapor deposition (UHV-CVD), molecular-beam epitaxy (MBE), and/or other suitable processes. Each of the source/drain features 232 may include N-type source/drain features and/or P-type source/drain features dependent upon types of transistors and varactors. Example N-type source/drain features may include silicon, phosphorus-doped silicon, arsenic-doped silicon, antimony-doped silicon, or other suitable material and may be in-situ doped during the epitaxial process by introducing an N-type dopant, such as phosphorus, arsenic, or antimony, or ex-situ doped using a junction implant process. Example P-type source/drain features may include germanium, gallium-doped silicon germanium, boron-doped silicon germanium, or other suitable material and may be in-situ doped during the epitaxial process by introducing a P-type dopant, such as boron or gallium, or ex-situ doped using a junction implant process. In some embodiments, each of the source/drain features 232 may include multiple semiconductor layers with different doping concentrations. For example, each of the source/drain features 232 may include a lightly doped semiconductor layer and a heavily doped semiconductor layer disposed over the lightly doped semiconductor layer.

Due to existence of the inner spacer features 226 and the isolation layer 230, the source/drain features 232 may be formed from exposed sidewalls of the channel members 208t, 208m, 208b. By controlling the duration of the epitaxial growth process for forming the source/drain features 232, when the portion of the source/drain features 232 grown from the channel member 208t merges with the portion of the source/drain features 232 grown from the channel member 208m to extend along sidewall surface of the inner spacer 226t/226m, a portion of the source/drain opening adjacent to the inner spacer features 226b will not be filled by the source/drain features 232 since the height of the bottommost inner spacer feature 226b is greater than other inner spacer features 226. Thus, a void (e.g., air gap) 234 will be formed between the source/drain feature 232 and the isolation layer 230 thereunder. That is, a portion of a sidewall surface of the bottommost inner spacer feature 226b is in direct contact with the source/drain feature 232, and another portion of the sidewall surface of the bottommost inner spacer feature 226b is partially exposed by the void (e.g., air gap) 234. In an embodiment, a lower portion of the sidewall surface of the bottommost inner spacer feature 226b is also in direct contact with the isolation layer 230. Forming the void (e.g., air gap) 234 adjacent to the bottommost inner spacer feature 226b and under the source/drain feature 232 advantageously leads to a reduced parasitic capacitance associated with the source/drain feature 232 and the gate structure (e.g., the portion 240b of the gate structure 240, shown in FIG. 13) that will be formed immediately adjacent to the bottommost inner spacer feature 226b.

Referring to FIGS. 1 and 13, method 100 includes a block 122 where the dummy gate stacks 210 are selectively removed to form gate trenches. After forming the source/drain feature 232, a contact etch stop layer (CESL) 236 and an interlayer dielectric (ILD) layer 238 are deposited over the structure 200. The CESL 236 may include silicon nitride, silicon oxynitride, and/or other materials known in the art and may be formed by ALD, plasma-enhanced chemical vapor deposition (PECVD) process and/or other suitable deposition or oxidation processes. As shown in FIG. 13, the CESL 236 may be deposited on top surfaces of the source/drain features 232, and sidewalls of the gate spacers 216s. The ILD layer 238 is deposited by a PECVD process or other suitable deposition technique over the structure 200 after the deposition of the CESL 236. The ILD layer 238 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, after formation of the ILD layer 238, the structure 200 may be annealed to improve integrity of the ILD layer 238.

A planarization process, such a chemical mechanical polishing (CMP) process may be performed to the structure 200 to remove excessive materials and expose the dummy gate electrode layer 212 in the dummy gate stacks 210. With the exposure of the dummy gate electrode layer 212, the dummy gate stacks 210 are selectively removed to form gate trenches (now filled by portions 240U of the gate structures 240). The removal of the dummy gate stacks 210 may include one or more etching process that are selective to the material in the dummy gate stacks 210. For example, the removal of the dummy gate stacks 210 may be performed using a selective wet etch, a selective dry etch, or a combination thereof.

Still referring to FIGS. 1 and 13, method 100 includes a block 124 where the dummy layers (e.g., the dummy layers 222b, 222m, 222t) are selectively removed to form gate openings. After the removal of the dummy gate stacks 210, the dummy layers (e.g., the dummy layers 222b, 222m, 222t) are selectively removed to form gate openings (now filled by portions 240t, 240m, 240b of the gate structures 240). The selective removal of the dummy layers may be implemented by a selective dry etch, a selective wet etch, or other selective etching process. An example selective wet etch process may include use of diluted hydrofluoric acid (DHF) or a mixture of hydrofluoric acid (HF) and, ammonium fluoride (NH₄F). An example selective dry etch process may include use of fluoride (F₂) vapor, anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. In some embodiments, the selective wet etching includes an APM etch (e.g., ammonia hydroxide-hydrogen peroxide-water mixture).

Still referring to FIGS. 1 and 13, method 100 includes a block 126 where gate structures 240 are formed in the gate trenches and gate openings. After the release of the channel member 208, the gate structure 240 is formed to wrap around each of the channel members 208 as shown in FIG. 13. While not explicitly shown, each of the gate structures 240 includes a gate dielectric layer (not separately labeled) and a gate electrode layer (not separately labeled) over the gate dielectric layer. In some embodiments, the gate dielectric layer includes an interfacial layer disposed on the channel members 208 and a high-k dielectric layer over the interfacial layer. Here, a high-k dielectric layer refers to a dielectric material having a dielectric constant greater than that of silicon dioxide, which is about 3.9. A low-k dielectric layer refers to a dielectric material having a dielectric constant no greater than that of silicon dioxide. In some embodiments, the interfacial layer includes silicon oxide. The high-k dielectric layer is then deposited over the interfacial layer using ALD, CVD, and/or other suitable methods. The high-k dielectric layer may include hafnium oxide. Alternatively, the high-k dielectric layer may include other high-k dielectrics, such as titanium oxide, hafnium zirconium oxide, tantalum oxide, hafnium silicon oxide, zirconium silicon oxide, lanthanum oxide, aluminum oxide, yttrium oxide, SrTiO₃, BaTiO₃, BaZrO, hafnium lanthanum oxide, lanthanum silicon oxide, aluminum silicon oxide, hafnium tantalum oxide, hafnium titanium oxide, (Ba,Sr)TiO₃ (BST), silicon nitride, silicon oxynitride, combinations thereof, or other suitable material. The gate electrode layer is then deposited over the gate dielectric layer using ALD, PVD, CVD, e-beam evaporation, or other suitable methods. The gate electrode layer may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride, titanium aluminum, titanium aluminum nitride, tantalum nitride, tantalum aluminum, tantalum aluminum nitride, tantalum aluminum carbide, tantalum carbonitride, aluminum, tungsten, nickel, titanium, ruthenium, cobalt, platinum, tantalum carbide, tantalum silicon nitride, copper, other refractory metals, or other suitable metal materials or a combination thereof. Further, where the structure 200 includes n-type transistors and p-type transistors, different gate electrode layers may be formed separately for n-type transistors and p-type transistors, which may include different work function metal layers (e.g., for providing different n-type and p-type work function metal layers).

The gate structure 240 includes an upper portion 240U formed in the gate trench and a lower portion 240L formed under the upper portion 240U and in the gate openings. In this illustrated embodiment, the lower portion 240L includes a topmost portion 240t formed between the channel members 208t and 208m, a middle portion 240m formed between the channel members 208m and 208b, and a bottommost portion 240b between the channel member 208b and the substrate 202. The upper portion 240U tracks the shape of the gate trench, and the portions 240t, 240m, and 240b track the shapes of the gate openings, respectively. In other words, the portions 240t, 240m, and 240b have different heights. That is, a ratio of a height of the bottommost portion 240b to a height of the topmost portion 240t is in a range between about 1.1 and about 3. A ratio of the height of the bottommost portion 240b to a height of the middle portion 240m may also be in a range between about 1.1 and about 3. The height of the middle portion 240m may be equal to, less than, or greater than the height of the topmost portion 240t. In an example, the height of the middle portion 240m is equal to the height of the topmost portion 240t. In some embodiments, the height of the bottommost portion 240b is substantially equal to the height H1 of the inner spacer feature 226b, and the height of the topmost portion 240t is substantially equal to the height H₂ of the topmost inner spacer feature 226t. By forming the void (e.g., air gap) 234, the fringe capacitance associated with the bottommost portion 240b of the gate structure 240 and the source/drain feature 232 may be advantageously reduced.

Referring to FIG. 1, method 100 includes a block 128 where further processes are performed to finish the fabrication of the semiconductor structure 200. For example, such further processes may form various contacts/vias, metal lines, power rails, as well as other multilayer interconnect features, such as ILD layers and/or etch stop layer (ESLs) over and/or under the structure 200, configured to connect the various features to form a functional circuit that includes the different semiconductor devices.

FIG. 14 is a flowchart illustrating an alternative method 300 of forming a semiconductor structure 200′ having a reduced parasitic capacitance according to embodiments of the present disclosure. Method 300 is described below in conjunction with FIGS. 15-24, which are fragmentary cross-sectional views of the structure 200′ at different stages of fabrication in the method 300.

Referring to FIGS. 14 and 15, method 300 includes a block 302 where a first sacrificial layer 206b1 and a stack 204′ of alternating channel layers 208 and second sacrificial layers (e.g., second sacrificial layers 206b2, 206m′, 206t′) are formed over the substrate 202. As shown in FIG. 15, the stack 204′ includes a number of second sacrificial layers (e.g., second sacrificial layers 206b2, 206m′, 206t′) and a number of channel layers (e.g., 208b, 208m, 208t) interleaved by the number of second sacrificial layers. The channel layers 208 and the second sacrificial layers (e.g., second sacrificial layers 206b2, 206m′, 206t′) include different materials to provide etch selectivity. Each channel layer 208 may include a semiconductor material such as, for example, Si, Ge, SiC, SiGe, GeSn, SiGeSn, SiGeCSn, other suitable semiconductor materials, or combinations thereof, while each of the second sacrificial layers (e.g., second sacrificial layers 206b2, 206m′, 206t′) has a material different from that of the channel layer 208. In one such example, the channel layers 208 may include elemental Si and the second sacrificial layers 206b2, 206m′, 206t′ may include SiGe. In this present embodiment, the first sacrificial layer 206b1 and the second sacrificial layers (e.g., second sacrificial layers 206b2, 206m′, 206t′) include the same material (e.g., silicon germanium) but different constituent atomic percentages to provide desired etching selectivity. In an embodiment, both the first sacrificial layer 206b1 and the second sacrificial layers 206b2, 206m′, 206t′ include SiGe, and germanium concentration of the first sacrificial layer 206b1 is less than germanium concentration of the second sacrificial layers 206b2, 206m′, 206t′. For example, germanium concentration of the first sacrificial layer 206b1 is in a range between about 10 at % and about 40 at %, and germanium concentrations of the second sacrificial layers 206b2, 206m′, 206t′ are in a range between about 20 at % and about 80 at %. In an embodiment, the second sacrificial layers 206b2, 206m′, 206t′ each may include the same germanium concentration.

The first sacrificial layer 206b1 has a thickness T4, and the bottommost second sacrificial layer 206b2 has a thickness T5. In the present embodiments, to facilitate the formation of air gaps to reduce parasitic capacitance (e.g., fringe capacitance) between metal gate structure and its adjacent source/drain features, a total thickness T6 of the first sacrificial layer 206b1 and the bottommost second sacrificial layer 206b2 is greater than a thickness of other second sacrificial layers (e.g., 206m′, 206t′). For example, the topmost second sacrificial layer 206t′ has a thickness T2, and a ratio of the thickness T6 to the thickness T2 is in a range between about 1.1 and about 3. If the ratio is greater than about 3, the space for forming metal gate structure under the bottommost channel layer 208b may be much bigger than the space for forming metal gate structure between the channel layer 208t and the channel layer 208m, leading to unwanted threshold voltage variations; if the ratio is less than about 1.1, it may not be easy to form a void (e.g., air gap), or the volume of the void (e.g., air gap) may be too small to effectively reduce the parasitic capacitance. For the same reasons, a ratio of the thickness T6 to a thickness of the middle second sacrificial layer 206m′ is in a range between about 1.1 and about 3. In an embodiment, the thickness T2 of the topmost second sacrificial layer 206t′ is substantially equal to the thickness of the middle second sacrificial layer 206m′. In an embodiment, the thickness T8 of the bottommost second sacrificial layer 206b2′ is substantially equal to the thickness T2. The thickness T7 may be equal to, greater than, or less than the thickness T8. In various embodiments, the channel layers 208 each have the same thickness T3, and the thickness T7 and the thickness T2 may be greater than the thickness T3.

In some embodiments, the first sacrificial layer 206b1, the second sacrificial layers 206b2, 206m′, 206t′ and the channel layers 208 may be deposited using an epitaxial process. Suitable epitaxial processes include vapor-phase epitaxy (VPE), ultra-high vacuum chemical vapor deposition (UHV-CVD), molecular beam epitaxy (MBE), and/or other suitable processes. As shown in FIG. 15, the second sacrificial layers and the channel layers 208 are deposited alternatingly, one-after-another, to form the stack 204′. It is noted that three layers of the second sacrificial layers and three layers of the channel layers 208 are alternately and vertically arranged as illustrated in FIG. 15, which are for illustrative purposes only and not intended to be limiting beyond what is specifically recited in the claims. It is understood that any number of second sacrificial layers and channel layers can be formed in the stack 204′. The number of layers depends on the desired number of channels members for the device 200′. In some embodiments, the number of the channel layers 208 is between 2 and 10, and the number of the second sacrificial layers is between 2 and 10.

Still referring to FIGS. 14 and 15, method 300 includes a block 304 where the first sacrificial layer 206b1, the stack 204′ and a top portion of the substrate 202 are patterned to form a fin-shaped active region 205′. The formation of the fin-shaped active region 205′ may be similar to the formation of the fin-shaped active region 205 and repeated description is omitted for reason of simplicity. After forming the fin-shaped active region 205′, the isolation feature 209 (shown in FIG. 3) may be formed adjacent to and around the lower portion of the fin-shaped active region 205′.

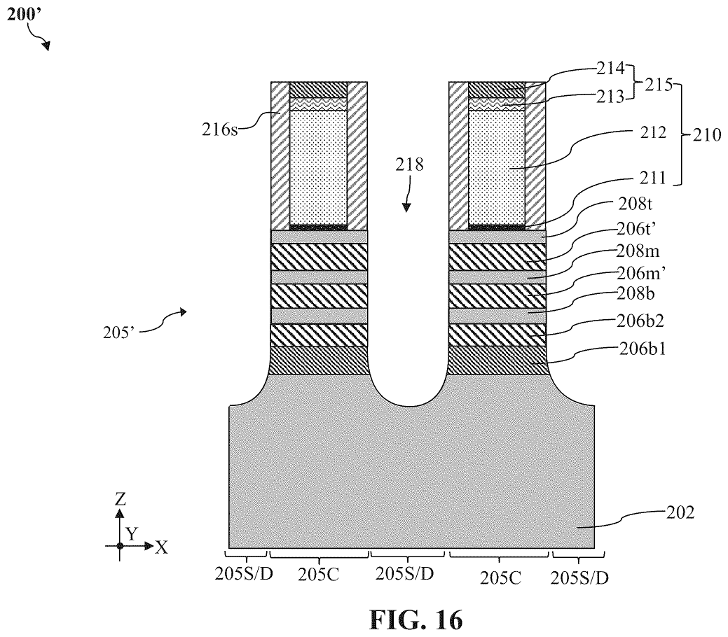

Referring to FIGS. 14 and 16, method 300 includes a block 306 where dummy gate stacks 210 are formed over channel regions 205C of the fin-shaped active region 205′. The formation of the dummy gate stacks 210 has been described above with reference to FIG. 5, and repeated description is thus omitted for reason of simplicity.

Referring to FIGS. 14 and 16, method 300 includes a block 308 where gate spacers 216s are formed to extend along sidewall surfaces of the dummy gate stacks 210. The formation of the gate spacers 216s has been described above with reference to FIG. 5, and repeated description is thus omitted for reason of simplicity.

Still referring to FIGS. 14 and 16, method 300 includes a block 310 where source/drain regions 205S/D of the fin-shaped active region 205′ are recessed to form source/drain openings 218. The formation of the source/drain openings 218 has been described above with reference to FIG. 5, and repeated description is thus omitted for reason of simplicity. In this embodiment, the source/drain openings 218 exposes sidewalls of the first sacrificial layer 206b1, the second sacrificial layers 206b2, 206m′, 206t′, and the channel layers 208b, 208m, 208t.

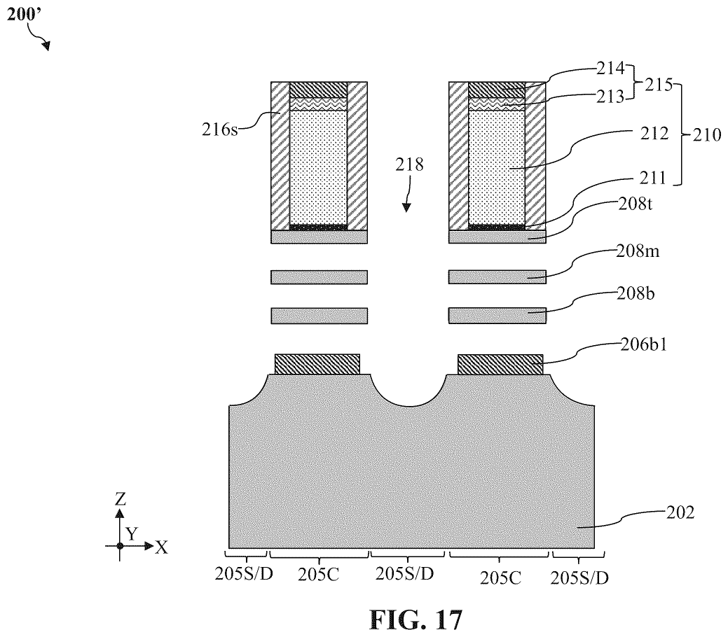

Referring to FIGS. 14 and 17-18, method 300 includes a block 312 where the second sacrificial layers (e.g., 206b2, 206m, 206t) are replaced with dummy layers. With reference to FIG. 17, after the formation of the source/drain openings 218, the second sacrificial layers (e.g., 206b2, 206m, 206t) interleaving the channel layers 208 in the channel region 205C are selectively removed. The selective removal of the second sacrificial layers (e.g., 206b2, 206m, 206t) releases the channel layers 208 to form channel members 208 shown in FIG. 17. Depending on the design, the channel members 208 may take form of nanowires, nanosheets, or other nanostructures. The selective removal of the second sacrificial layers (e.g., 206b2, 206m, 206t) forms spaces between and around adjacent channel members 208. The selective removal of the second sacrificial layers (e.g., 206b2, 206m, 206t) may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture). Etch selectivity between the second sacrificial layers 206b2, 206m′, 206t′ and the first sacrificial layer 206b1 is less than the Etch selectivity between the second sacrificial layers 206b2, 206m′, 206t′ and the channel layers 208. In an embodiment, the first sacrificial layer 206b1 has also been slightly recessed during the selective removal of the second sacrificial layers. The extent at which the first sacrificial layer 206b1 is recessed is less than that of the channel layers 208. As represented by FIG. 17, after the selective removal of the second sacrificial layers 206b2, 206m′, 206t′, a width of the first sacrificial layer 206b1 along the X direction is less than the width of the channel members 208 along the X direction.

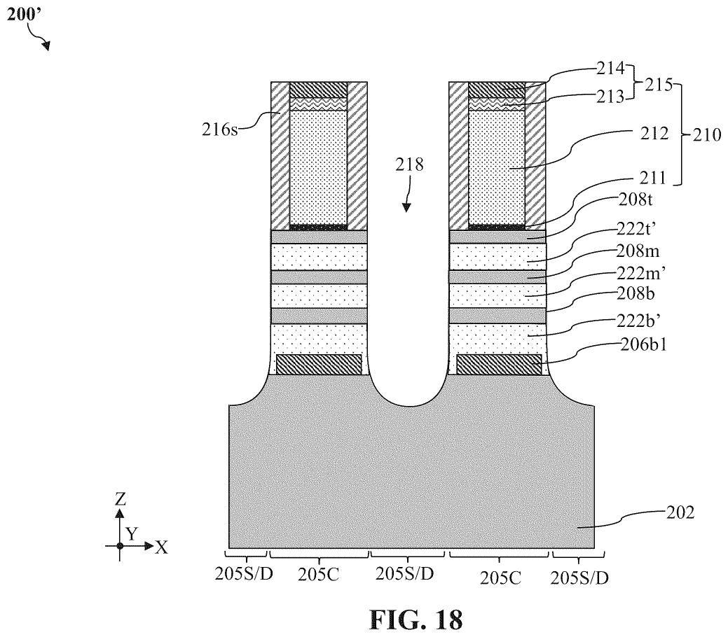

With reference to FIG. 18, after the selective removal of the second sacrificial layers (e.g., second sacrificial layers 206b2, 206m′, 206t′), dummy layers (e.g., dummy layers 222t′, 222m′, 222b′) are formed to fill spaces released by the second sacrificial layers. As illustrated by FIG. 18, the dummy layers 222t′, 222m′, 222b′ are interleaved by the channel members 208. In the present embodiment, the dummy layers 222t′, 222m′, 222b′ have different heights (or thicknesses). For example, a thickness of the bottommost dummy layer 222b′ is substantially equal to the thickness T6 and is greater than thicknesses of the dummy layers 222t′ and 222m′. In an embodiment, the thickness of the dummy layer 222m′ is substantially equal to the thickness of the dummy layer 222t′. In this present embodiment, the bottommost dummy layer 222b′ is disposed adjacent to and on sidewall and top surface of the first sacrificial layer 206b1. The formation of the dummy layers 222t′, 222m′, 222b′ is similar to the formation of the dummy layers 222t, 222m, 222b, and repeated description is omitted for reason of simplicity.

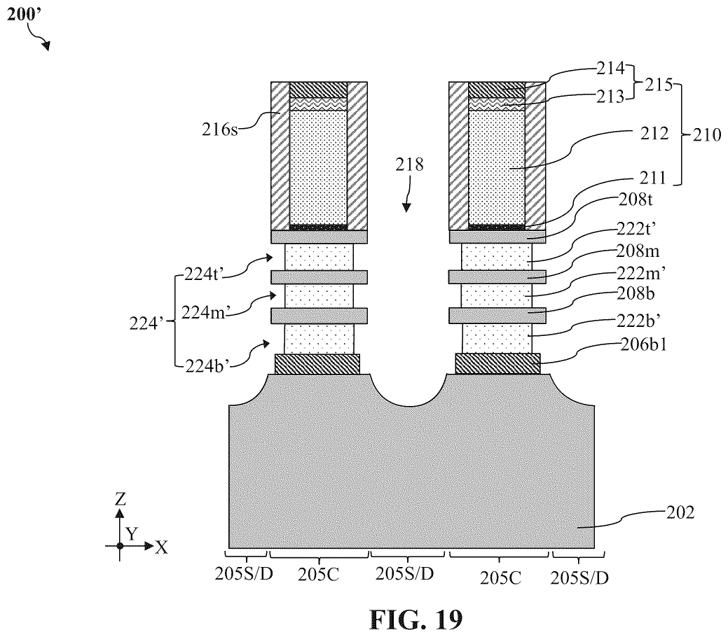

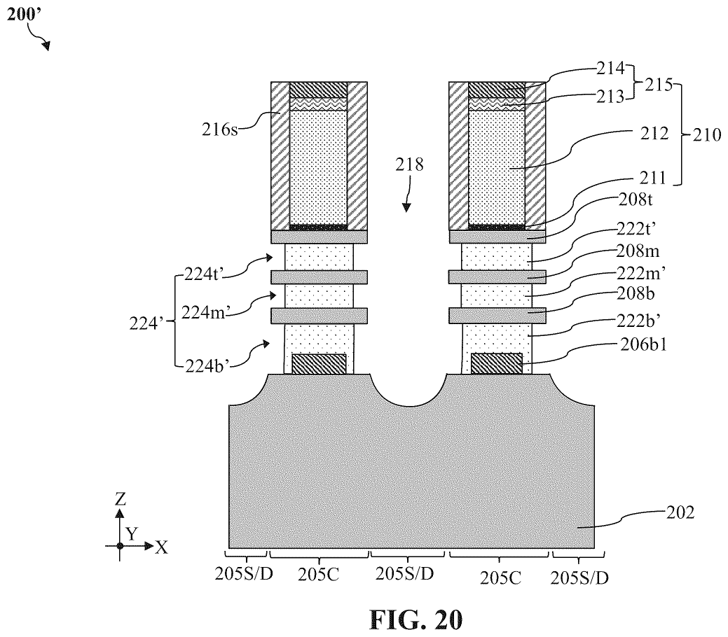

Referring to FIGS. 14 and 19, method 300 includes the block 114 where inner spacer recesses (e.g., inner spacer recesses 224t′, 224m′, 224b′) are formed. Operation in block 114 has been described above and repeated description is omitted for reason of simplicity. It is noted that, in this present embodiment, the bottommost inner spacer recess 224b′ spans a height greater than other inner spacer recesses 224t′ and 224m′. For example, a ratio of a height of the bottommost inner spacer recess 224b′ to a height of the inner spacer recess 224t′ is in a range between about 1.1 and about 3. In an embodiment, a ratio of a height of the bottommost inner spacer recess 224b′ to a height of the inner spacer recess 224m is also in a range between about 1.1 and about 3. In some instances, the height of the bottommost inner spacer recess 224b′ is substantially equal to the thickness T6, and the height of the topmost inner spacer recess 224t′ is substantially equal to the thickness T2. The inner spacer recesses 224t′, 224m′, 224b′ may be collectively or individually referred to as the inner spacer recesses 224′. In the present embodiments, the inner spacer recess 224b′ exposes sidewall surface of the dummy layer 222b′ and sidewall surface of the first sacrificial layer 206b1. In another alternative embodiment, depending on the extent at which the first sacrificial layer 206b1 has been recessed during the selective removal of the second sacrificial layers 206b2, 206m′, 206t′ and the extent at which the dummy layers are recessed during performing of operation in block 114, the inner spacer recess 224b′ may only expose the sidewall surface of the dummy layer 222b′, as represented by FIG. 20.

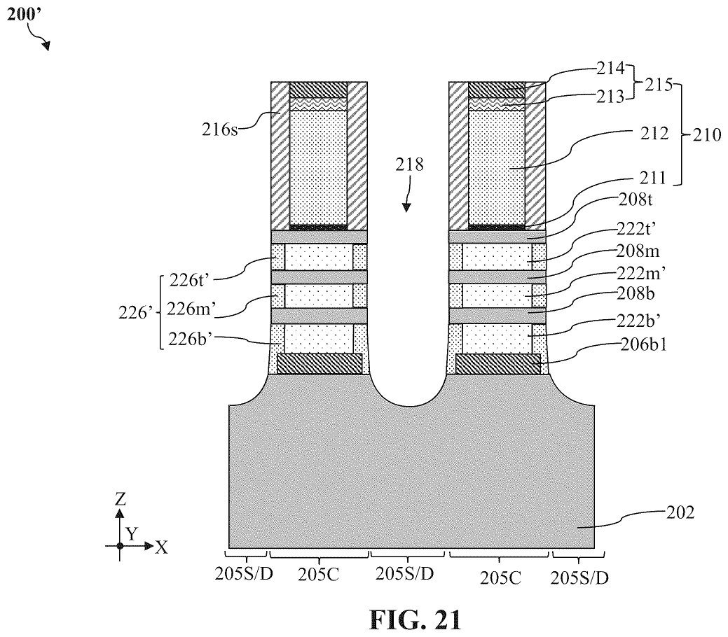

Referring to FIGS. 14 and 21, method 300 includes the block 116 where inner spacer features (e.g., inner spacer feature 226t′, 226m′, 226b′) are formed in the inner spacer recesses 224′. The inner spacer features track the shapes of the corresponding inner spacer recesses, respectively. The inner spacer feature 226t′, 226m′, 226b′ may be collectively or individually referred to as the inner spacer features 226′ or the inner spacer feature 226′, respectively. Operation in block 116 has been described above and repeated description is omitted for reason of simplicity. It is noted that, in this present embodiment, the bottommost inner spacer feature 226b′ extends over both the substrate 202 and the first sacrificial layer 206b1. As illustrated by FIG. 21, a portion of the bottommost inner spacer feature 226b′ is disposed on and in direct contact with the first sacrificial layer 206b1. In another alternative embodiment discussed with reference to FIG. 20, after performing operation in block 116, the bottommost inner spacer feature 226b′ may be laterally separated from the first sacrificial layer 206b1 by the dummy layer 222b′.

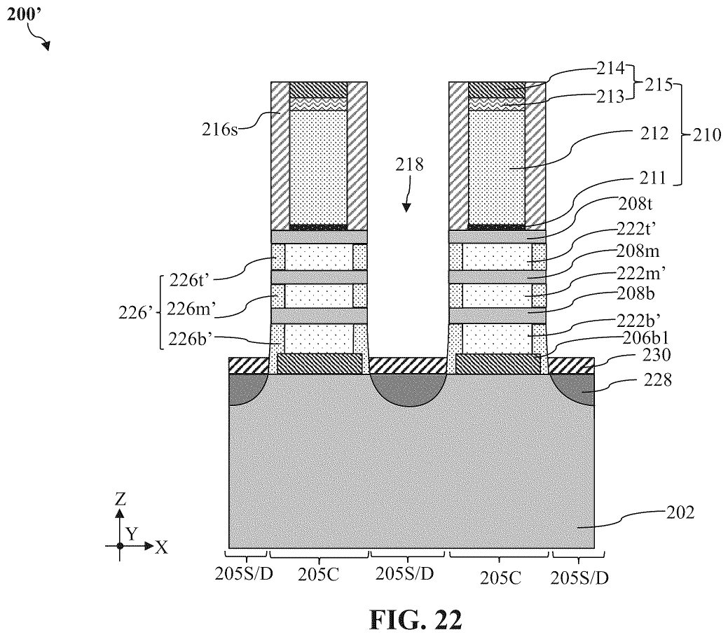

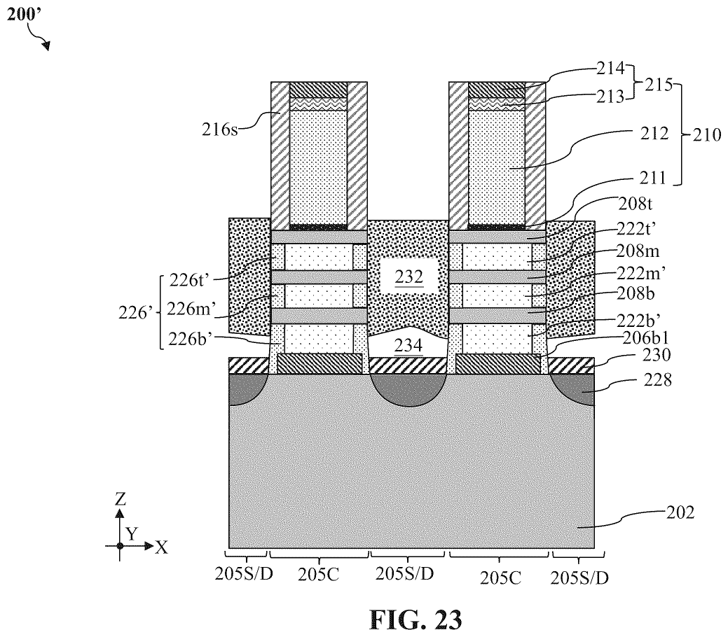

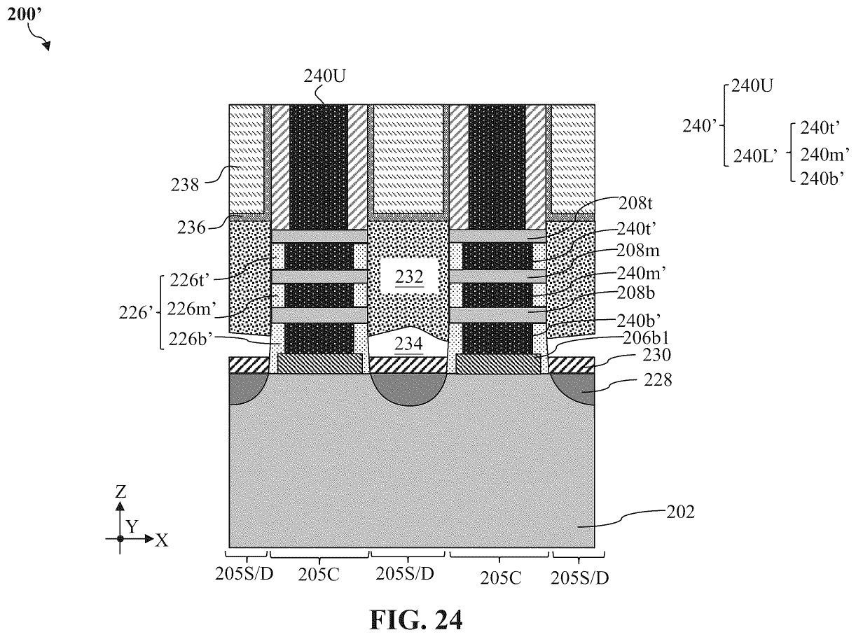

Referring to FIGS. 14 and 22, method 300 includes the block 118 where the undoped semiconductor layer 228 and the isolation layer 230 are formed in the lower portion of the source/drain opening 218. Referring to FIGS. 14 and 23, method 300 includes the block 120 where source/drain features 232 are formed in the source/drain openings 218 and over the isolation layers 230. Referring to FIGS. 14 and 24, method 300 includes the block 122 where the dummy gate stacks 210 are selectively removed to form gate trenches, the block 124 where the dummy layers (e.g., the dummy layers 222b′, 222m′, 222t′) are selectively removed to form gate openings, and the block 126 where gate structures 240′ are formed in the gate trenches and gate openings. Referring to FIG. 14, method 300 includes the block 128 where further processes are performed to finish the fabrication of the semiconductor structure 200′. Operations in blocks 118, 120, 122, 124, 126, and 128 have been described above with reference to FIG. 1, and repeated description is omitted for reason of simplicity. The gate structure 240′ in the semiconductor structure 200′ includes the upper portion 240U formed in the gate trench and a lower portion 240L′ formed under the upper portion 240U. In this illustrated embodiment, the lower portion 240L′ includes the topmost portion 240t′ formed between the channel members 208t and 208m, the middle portion 240m′ formed between the channel members 208m and 208b, and a bottommost portion 240b′ between the channel member 208b and the first sacrificial layer 206b1. The height of the bottommost portion 240b′ is less than the height of the bottommost inner spacer feature 226b′. By forming the void (e.g., air gap) 234, the fringe capacitance associated with the bottommost portion 240b′ of the gate structure 240′ and the source/drain feature 232 may be advantageously reduced. By forming the first sacrificial layer 206b1, uniformity among different parts (e.g., 240b′, 240m′, 240t′) of the lower portion 240L′ of the gate structure 240′ may be achieved. In another embodiment discussed with reference to FIG. 20, after performing operations in blocks 118, 120, 122, 124, 126, and 128, the bottommost portion 240b′ of the gate structure 240′ may have a profile similar to the bottommost dummy layer 222b′ shown in FIG. 20.

FIG. 25 is a flowchart illustrating an alternative method 500 of forming a semiconductor structure 200″ having a reduced parasitic capacitance according to embodiments of the present disclosure. Method 500 is described below in conjunction with FIGS. 26-35, which are fragmentary cross-sectional views of the structure 200″ at different stages of fabrication in the method 500.

Referring to FIGS. 25 and 26, method 500 includes a block 502 where a first sacrificial layer 206b1′ and a stack 204″ of alternating channel layers 208 and second sacrificial layers (e.g., second sacrificial layers 206b2′, 206m″, 206t″) are formed over the substrate 202. As shown in FIG. 26, the stack 204″ includes a number of second sacrificial layers (e.g., second sacrificial layers 206b2′, 206m″, 206t″) and a number of channel layers (e.g., 208b, 208m, 208t) interleaved by the number of second sacrificial layers. The channel layers 208 and the second sacrificial layers (e.g., second sacrificial layers 206b2′, 206m″, 206t″) include different materials to provide etch selectivity. Each channel layer 208 may include a semiconductor material such as, for example, Si, Ge, SiC, SiGe, GeSn, SiGeSn, SiGeCSn, other suitable semiconductor materials, or combinations thereof, while each of the second sacrificial layers (e.g., second sacrificial layers 206b2′, 206m″, 206t″) has a material different from that of the channel layer 208. In one such example, the channel layers 208 may include elemental Si and the second sacrificial layers 206b2′, 206m″, 206t″ may include SiGe. In this present embodiment, the first sacrificial layer 206b1′ and the second sacrificial layers (e.g., second sacrificial layers 206b2′, 206m″, 206t″) include the same material (e.g., silicon germanium) but different constituent atomic percentages to provide desired etching selectivity. In an embodiment, both the first sacrificial layer 206b1′ and the second sacrificial layers 206b2′, 206m″, 206t″ include SiGe, and germanium concentration of the first sacrificial layer 206b1′ is greater than germanium concentration of the second sacrificial layers 206b2′, 206m″, 206t″ such that the first sacrificial layer 206b1′ may be selectively removed with respect to the second sacrificial layers 206b2′, 206m″, 206t″. In an embodiment, the second sacrificial layers 206b2′, 206m″, 206t″ each may include the same germanium concentration.

The first sacrificial layer 206b1′ has a thickness T7, and the bottommost second sacrificial layer 206b2′ has a thickness T8. In the present embodiments, to facilitate the formation of voids (e.g., air gaps) to reduce parasitic capacitance (e.g., fringe capacitance) between metal gate structure and its adjacent source/drain features, a total thickness T9 of the first sacrificial layer 206b1′ and the bottommost second sacrificial layer 206b2′ is greater than a thickness of other second sacrificial layers (e.g., 206m″, 206t″). In an embodiment, the thickness T2 of the topmost second sacrificial layer 206t″ is substantially equal to the thickness of the middle sacrificial layer 206m″. In an embodiment, the thickness T8 of the bottommost second sacrificial layer 206b2′ is substantially equal to the thickness T2. The thickness T7 may be equal to, greater than, or less than the thickness T8. In various embodiments, the channel layers 208 each have the same thickness T3, and the thickness T2 may be greater than the thickness T3.

In some embodiments, the first sacrificial layer 206b1′, the second sacrificial layers 206b2′, 206m″, 206t″ and the channel layers 208 may be deposited using an epitaxial process. Suitable epitaxial processes include vapor-phase epitaxy (VPE), ultra-high vacuum chemical vapor deposition (UHV-CVD), molecular beam epitaxy (MBE), and/or other suitable processes. As shown in FIG. 26, the second sacrificial layers and the channel layers 208 are deposited alternatingly, one-after-another, to form the stack 204″. It is noted that three layers of the second sacrificial layers and three layers of the channel layers 208 are alternately and vertically arranged as illustrated in FIG. 26, which are for illustrative purposes only and not intended to be limiting beyond what is specifically recited in the claims. It is understood that any number of second sacrificial layers and channel layers can be formed in the stack 204″. The number of layers depends on the desired number of channels members for the device 200″. In some embodiments, the number of the channel layers 208 is between 2 and 10, and the number of the second sacrificial layers is between 2 and 10.

Still referring to FIGS. 25 and 26, method 500 includes a block 504 where the first sacrificial layer 206b1′, the stack 204″ and a top portion of the substrate 202 are patterned to form a fin-shaped active region 205″. The fin-shaped active region 205″ may be patterned from the stack 204″, the first sacrificial layer 206b1′ and the substrate 202 using a lithography process and an etch process. The formation of the fin-shaped active region 205″ may be similar to the formation of the fin-shaped active region 205 and repeated description is omitted for reason of simplicity. After forming the fin-shaped active region 205″, the isolation feature 209 (shown in FIG. 3) may be formed adjacent to and around the lower portion of the fin-shaped active region 205″.

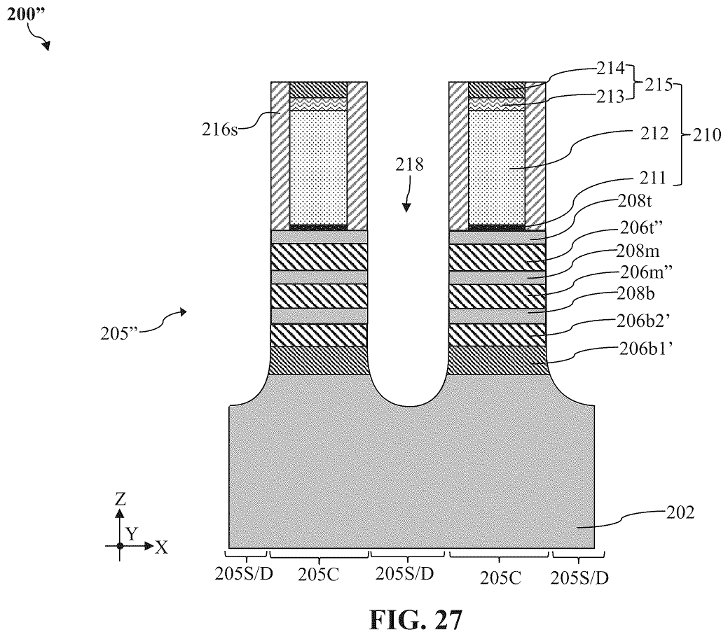

Referring to FIGS. 25 and 27, method 500 includes a block 506 where the dummy gate stacks 210 are formed over channel regions 205C of the fin-shaped active region 205″. The formation of the dummy gate stacks 210 has been described above with reference to FIG. 5, and repeated description is thus omitted for reason of simplicity.

Referring to FIGS. 25 and 27, method 500 includes a block 508 where the gate spacers 216s are formed to extend along sidewall surfaces of the dummy gate stacks 210. The formation of the gate spacers 216s has been described above with reference to FIG. 5, and repeated description is thus omitted for reason of simplicity.

Still referring to FIGS. 25 and 27, method 500 includes a block 510 where source/drain regions 205S/D of the fin-shaped active region 205″ are recessed to form source/drain openings 218. The formation of the source/drain openings 218 has been described above with reference to FIG. 5, and repeated description is thus omitted for reason of simplicity. In this embodiment, the source/drain openings 218 exposes sidewalls of the first sacrificial layer 206b1′, the second sacrificial layers 206b2′, 206m″, 206t″, and the channel layers 208b, 208m, 208t.

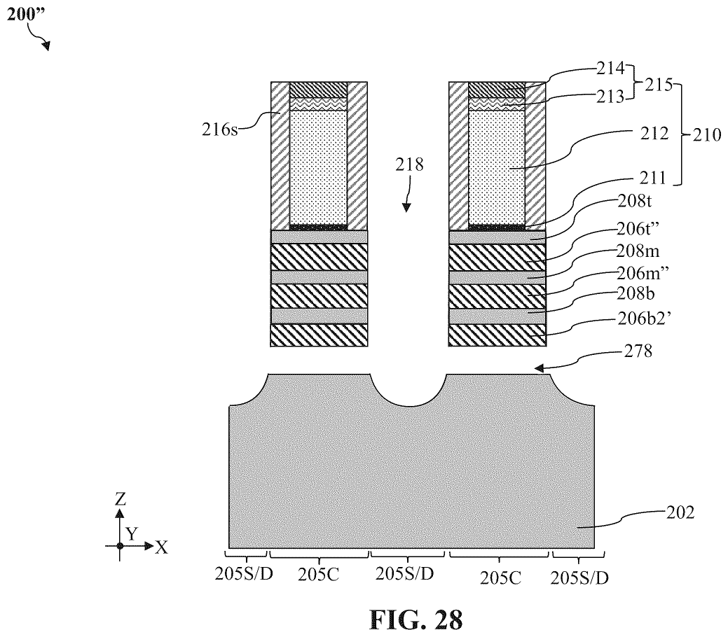

Referring to FIGS. 25 and 28-29, method 500 includes a block 512 where the first sacrificial layer 206b1′ is replaced with a first dummy layer 280. With reference to FIG. 28, after the formation of the source/drain openings 218, an etching process is performed to selectively remove the first sacrificial layer 206b1′ in the channel region 205C without substantially etching the second sacrificial layers (e.g., 206b2′, 206m″, 206t″) and the channel layers 208. The selective removal of the first sacrificial layer 206b1′ in the channel region 205C forms space 278 under the bottommost second sacrificial layer 206b2′.

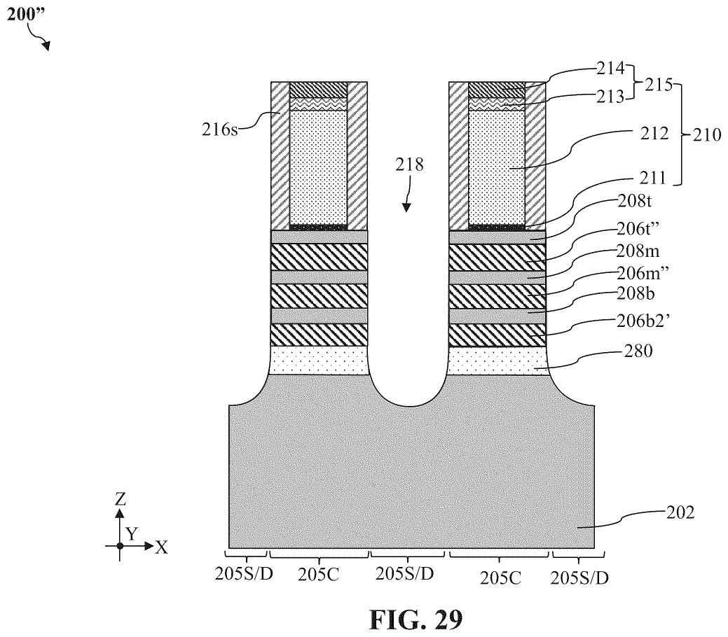

With reference to FIG. 29, after the selective removal of the first sacrificial layer 206b1′, the first dummy layer 280 is formed to fill space 278 released by the first sacrificial layer 206b1′. As illustrated by FIG. 29, the first dummy layer 280 is disposed between the bottommost second sacrificial layer 206b2′ and the substrate 202. The first dummy layer 280 may include silicon oxide, silicon nitride, silicon oxynitride, silicon carbonitride, silicon oxycarbonitride, high-K dielectric materials (e.g., aluminum oxide, hafnium oxide), other suitable materials, or combinations thereof, and may be deposited using plasma enhanced chemical vapor deposition (PECVD) or ALD or other suitable methods. In an embodiment, the first dummy layer 280 includes silicon oxynitride. The formation of the first dummy layer 280 may be similar to the formation of the dummy layers 222t, 222m, 222b described with reference to FIGS. 7-8, and repeated description is omitted for reason of simplicity.

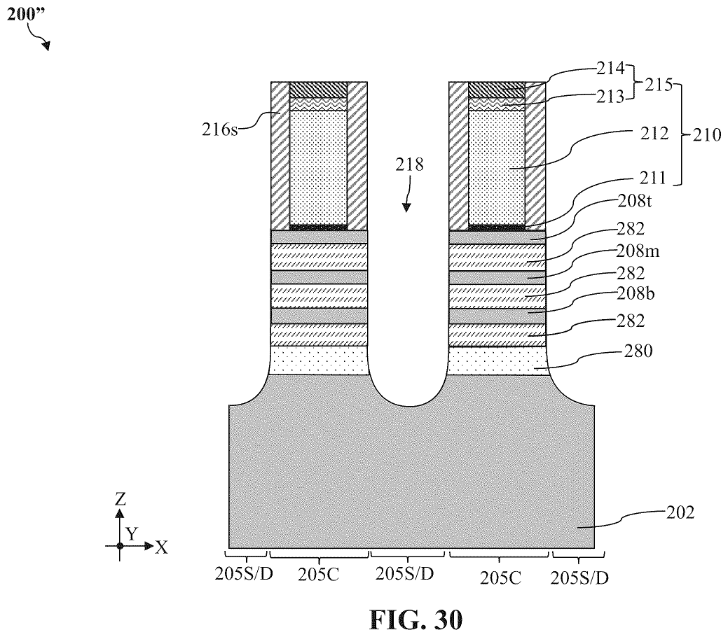

Referring to FIGS. 25 and 30, method 500 includes a block 514 where the second sacrificial layers (e.g., 206b2′, 206m″, 206t″) are replaced with second dummy layers 282. After the formation of the first dummy layer 280, the second sacrificial layers (e.g., 206b2′, 206m″, 206t″) interleaving the channel layers 208 in the channel region 205C are selectively removed, and the second dummy layers 282 are formed. The formation of the second dummy layers 282 is similar to the formation of the dummy layers 222t, 222m, 222b described with reference to FIGS. 7-8. For example, a first etching process is performed to selectively remove the second sacrificial layers (e.g., 206b2′, 206m″, 206t″) without substantially etching the channel layers 208 and the first dummy layer 280. Then, a dielectric material layer is deposited over the structure 200″. The dielectric material layer may include silicon oxide, silicon nitride, silicon oxynitride, silicon carbonitride, silicon oxycarbonitride, high-K dielectric materials (e.g., aluminum oxide, hafnium oxide), other suitable materials, or combinations thereof, and may be deposited using plasma enhanced chemical vapor deposition (PECVD) or ALD or other suitable methods. A second etching process is performed to selectively etch back the dielectric material layer without substantially etching the channel layers 208 and the first dummy layer 280, thereby forming the second dummy layers 282. In an embodiment, the first dummy layer 280 includes silicon oxynitride, and the second dummy layers 282 include silicon oxide. The bottommost second dummy layer 282 is over and in direct contact with the first dummy layer 280. A height of the first dummy layer 280 may be equal to the thickness T7, and a height of the bottommost second dummy layer 282 may be equal to the thickness T8.

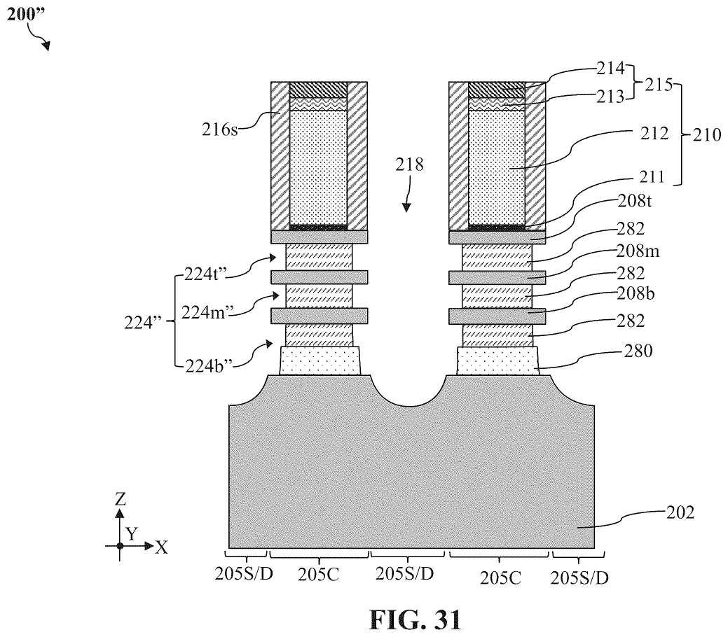

Referring to FIGS. 25 and 31, method 500 includes the block 114 where inner spacer recesses (e.g., inner spacer recesses 224t″, 224m″, 224b″) are formed. Operation in block 114 has been described above and repeated description is omitted for reason of simplicity. It is noted that, in this present embodiment, the bottommost inner spacer recess 224b″ spans a height greater than other inner spacer recesses 224t″ and 224m″. For example, a ratio of a height of the bottommost inner spacer recess 224b″ to a height of the inner spacer recess 224t″ is in a range between about 1.1 and about 3, a ratio of the height of the bottommost inner spacer recess 224b″ to a height of the inner spacer recess 224m″ is also in a range between about 1.1 and about 3. In an example, the height of the inner spacer recess 224b″ is substantially equal to the thickness T9, and the height of the topmost inner spacer recess 224t″ is substantially equal to the thickness T2. The inner spacer recesses 224t″, 224m″, 224b″ may be collectively or individually referred to as the inner spacer recesses 224″. In the present embodiments, the bottommost inner spacer recess 224b″ exposes sidewall surface of the first dummy layer 280 and sidewall surface of the bottommost second dummy layer 282. The etching process for recessing the first dummy layer 280 and the second dummy layers 282 to form the inner spacer recess 224″ may etch the first dummy layer 280 and the second dummy layers 282 at a same rate, or at different rates. In this illustrated embodiment, this etching process etches the second dummy layers 282 at a rate higher than it etches the first dummy layer 280. In another alternative embodiments, this etching process may etch the second dummy layers 282 at a rate lower than it etches the first dummy layer 280 or at the same rate as it etches the first dummy layer 280. That is, after the forming of the inner spacer recesses 224″, a width of the bottommost second dummy layer 282 may be equal to, less than, or greater than a width of the first dummy layer 280.

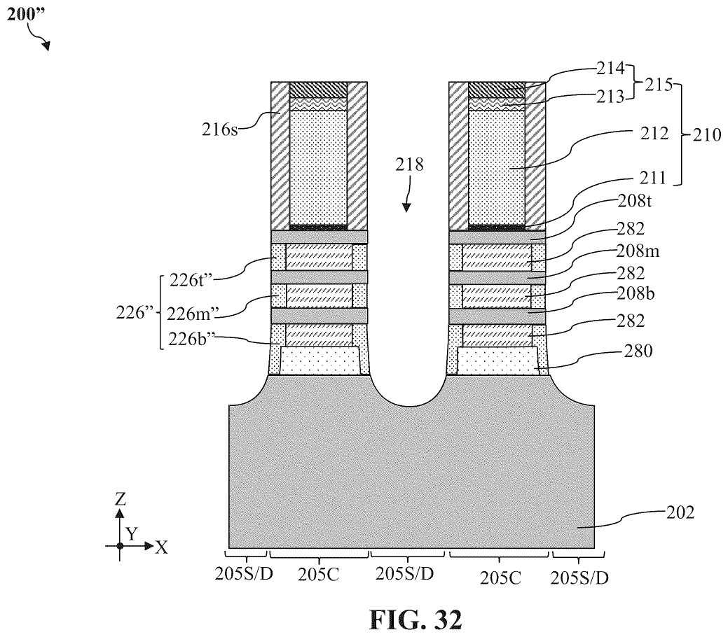

Referring to FIGS. 25 and 32, method 500 includes the block 116 where inner spacer features (e.g., inner spacer feature 226t″, 226m″, 226b″) are formed in the inner spacer recesses 224″. The inner spacer feature 226t″, 226m″, 226b″ may be collectively or individually referred to as the inner spacer features 226″ or the inner spacer feature 226″, The inner spacer features 226″ track the shapes of the corresponding inner spacer recesses 224″, respectively. Operation in block 116 has been described above and repeated description is omitted for reason of simplicity.

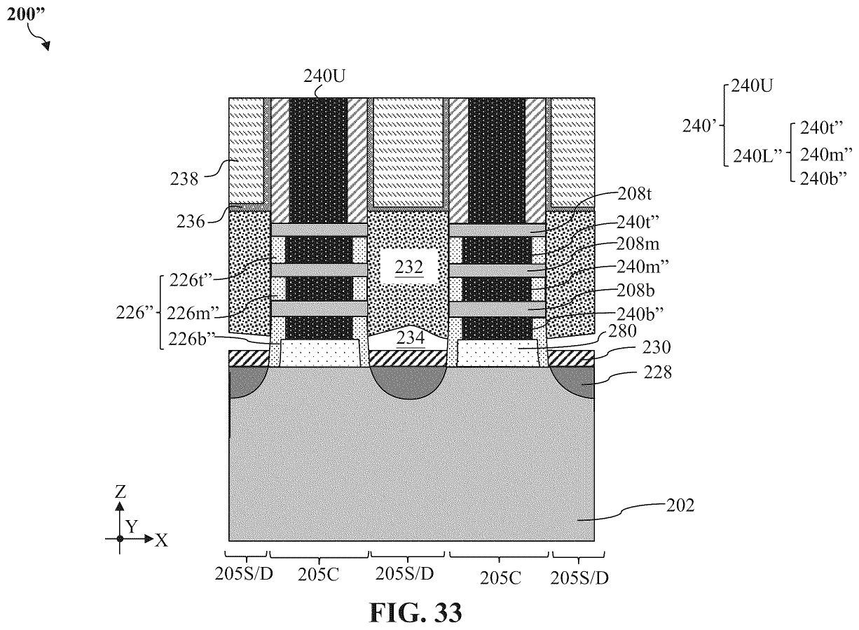

Referring to FIGS. 25 and 33, method 500 includes the block 118 where the undoped semiconductor layer 228 and the isolation layer 230 are formed in the lower portion of the source/drain opening 218. Referring to FIGS. 25 and 33, method 500 includes the block 120 where source/drain features 232 are formed in the source/drain openings 218 and over the isolation layers 230. Referring to FIGS. 25 and 33, method 500 includes the block 122 where the dummy gate stacks 210 are selectively removed to form gate trenches. Operations in blocks 118, 120 and 122 have been described above with reference to FIG. 1, and repeated description is omitted for reason of simplicity.

Referring to FIGS. 25 and 33, method 500 includes the block 516 where the second dummy layers 282 are selectively removed to form gate openings. In an embodiment, an etching process is performed to selectively remove the second dummy layers 282 without substantially etching the first dummy layer 280, the channel members 208, and the inner spacer features 226″.

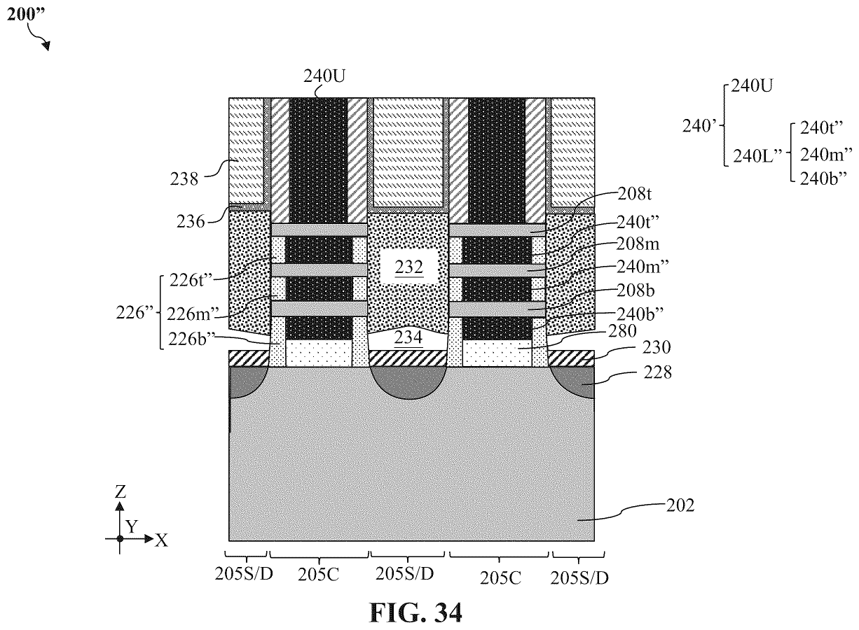

Referring to FIGS. 25 and 33, method 500 includes a block 518 where gate structures 240″ are formed in the gate trenches and gate openings. Referring to FIG. 25, method 500 includes a block 520 where further processes are performed to finish the fabrication of the semiconductor structure 200″. Operations in blocks 518 and 520 are similar to the operations in 126 and 128 described above with reference to FIG. 1, and repeated description is omitted for reason of simplicity. The gate structure 240″ in the semiconductor structure 200″ includes the upper portion 240U formed in the gate trench and a lower portion 240L″ formed under the upper portion 240U. In this illustrated embodiment, the lower portion 240L″ includes the topmost portion 240t″ formed between the channel members 208t and 208m, the middle portion 240m″ formed between the channel members 208m and 208b, and a bottommost portion 240b″ between the channel member 208b and the first dummy layer 280. The height of the bottommost portion 240b″ is less than the height of the bottommost inner spacer feature 226b″. By forming the void (e.g., air gap) 234, the fringe capacitance associated with the bottommost portion 240b″ of the gate structure 240″ and the source/drain feature 232 may be advantageously reduced. By forming the first dummy layer 280, uniformity among different part (e.g., 240b″, 240m″, 240t″) of the lower portion 240L″ of the gate structure 240″ may be achieved. In this illustrated embodiment, the bottommost portion 240b″ of the gate structure 240″ spans a first distance along the X direction, the first dummy layer 280 spans a second distance along the X direction, and the first distance is less than the second distance. In another alternative embodiment represented by FIG. 33, the first distance is substantially equal to the second distance, and the bottommost inner spacer feature 226″ has a corresponding profile represented by FIG. 33. In another alternative embodiment represented by FIG. 34, the first distance is substantially greater than the second distance, and the bottommost inner spacer feature 226″ has a corresponding profile represented by FIG. 34.

Embodiments of the present disclosure provide advantages. Methods of the present disclosure include forming a void (e.g., air gap) between source/drain feature and substrate to reduce parasitic capacitance associated with the source/drain feature and adjacent gate structures. Device performance may be advantageously improved. In an embodiment, a semiconductor layer is disposed between a bottommost portion of the gate structure and the substrate. A composition of the semiconductor layer is different than a composition of the substrate. In another embodiment, a dielectric layer is disposed between the bottommost portion of the gate structure and the substrate. By forming the semiconductor layer or the dielectric layer, different portions of the gate structure wrapping around nanostructures may provide substantially uniform electrical characteristic.

The present disclosure provides for many different embodiments. Semiconductor structures and methods of fabrication thereof are disclosed herein. In one exemplary aspect, the present disclosure is directed to a method. The method includes forming a fin-shaped active region over a substrate, the fin-shaped active region comprising a plurality of channel layers interleaved by a plurality of sacrificial layers, wherein a thickness of a bottommost sacrificial layer of the plurality of sacrificial layers is greater than a thickness of a topmost sacrificial layer of the plurality of sacrificial layers, forming a gate stack over a channel region of the fin-shaped active region, recessing a source/drain region of the fin-shaped active region to form a source/drain opening, replacing the plurality of sacrificial layers with a plurality of dummy layers, epitaxially forming a source/drain feature in the source/drain opening, wherein the source/drain feature is spaced apart from the substrate by an air gap, and replacing the gate stack and the plurality of dummy layers with a gate structure.

In some embodiments, the method may also include recessing the plurality of dummy layers to form inner spacer recesses, and forming inner spacer features in the inner spacer recesses. In some embodiments, the air gap spans a height less than a thickness of a bottommost inner spacer feature of the inner spacer features. In some embodiments, a thickness of a bottommost inner spacer feature of the plurality of the inner spacer features may be greater than a thickness of a topmost inner spacer feature of the plurality of the inner spacer features. In some embodiments, the method may also include, after the forming of the inner spacer features, forming an undoped semiconductor layer in the source/drain opening, and forming a dielectric layer over the undoped semiconductor layer, and the air gap is disposed between the dielectric layer and the source/drain feature. In some embodiments, a top surface of the dielectric layer may be lower than a top surface of a bottommost inner spacer feature of the inner spacer features. In some embodiments, the bottommost sacrificial layer may include a first sacrificial layer and a second sacrificial layer over the first sacrificial layer, germanium concentration of the first sacrificial layer is less than germanium concentration of the second sacrificial layer, and the replacing of the plurality of sacrificial layers with the plurality of dummy layers may include selectively removing the second sacrificial layer without fully removing the first sacrificial layer. In some embodiments, the replacing of the plurality of sacrificial layers with the plurality of dummy layers may include performing a first etching process to selectively removing the plurality of sacrificial layers to form a plurality of openings, depositing a dielectric material layer over the substrate, and performing a second etching process to etch back the dielectric material layer, thereby forming the plurality of dummy layers in the plurality of openings, respectively. In some embodiments, the bottommost sacrificial layer may include a first sacrificial layer and a second sacrificial layer over the first sacrificial layer, germanium concentration of the first sacrificial layer is greater than germanium concentration of the second sacrificial layer, and the replacing of the plurality of sacrificial layers with the plurality of dummy layers may include replacing of the first sacrificial layer with a first dummy layer, and prior to the replacing of the first sacrificial layer with the first dummy layer, replacing of the second sacrificial layer with a second dummy layer.

In another exemplary aspect, the present disclosure is directed to a method. The method includes forming a source/drain opening extending through a fin-shaped active region that comprises a plurality of channel layers interleaved by a plurality of sacrificial layers over a substrate, wherein a distance between a bottommost layer of the plurality of channel layers and the substrate is greater than a distance between two adjacent layers of the plurality of channel layers, replacing the plurality of sacrificial layers with a plurality of dielectric layers, and forming a source/drain feature in the source/drain opening, wherein an air gap is disposed vertically between the source/drain feature and the substrate.

In some embodiments, the method may also include recessing the plurality of dielectric layers to form inner spacer recesses, and forming inner spacer features in the inner spacer recesses, wherein a bottommost inner spacer feature of the inner spacer features is thicker than one inner spacer feature of the inner spacer features disposed over the bottommost inner spacer feature. In some embodiments, the inner spacer features may include a topmost inner spacer feature, the bottommost inner spacer feature, and a middle inner spacer feature disposed between the bottommost inner spacer feature and topmost inner spacer feature, and a thickness of the bottommost inner spacer feature may be greater than both a thickness of the middle inner spacer feature and a thickness of the topmost inner spacer feature. In some embodiments, the thickness of the middle inner spacer feature may be equal to the thickness of the topmost inner spacer feature. In some embodiments, a ratio of the thickness of the bottommost inner spacer feature to the thickness of the middle inner spacer feature may be about 1.1 to about 3. In some embodiments, the method may also include selectively removing the plurality of dielectric layers, and forming a gate structure wrapping around the plurality of channel layers, wherein a portion of the gate structure disposed under a bottommost channel layer of the plurality of channel layers is thicker than a portion of the gate structure disposed immediately under a topmost channel layer of the plurality of channel layers. In some embodiments, the method may also include forming an isolation layer in the source/drain opening and on the substrate, wherein the air gap exposes the isolation layer.

In yet another exemplary aspect, the present disclosure is directed to a semiconductor device. The semiconductor device includes a plurality of nanostructures over a substrate, wherein a distance between a bottommost nanostructure of the plurality of nanostructures and the substrate is greater than a distance between two adjacent nanostructures of the plurality of nanostructures, a source/drain feature coupled to the plurality of nanostructures, an air gap disposed vertically between the source/drain feature and the substrate, and a gate structure wrapping around and over each of the plurality of nanostructures.

In some embodiments, the semiconductor device may also include a plurality of inner spacer features disposed between the gate structure and the source/drain feature, wherein a bottommost inner spacer feature of the plurality of inner spacer features is thicker than other inner spacer features of the plurality of the inner spacer features. In some embodiments, the semiconductor device may also include a dielectric layer adjacent to the bottommost inner spacer feature, wherein the air gap exposes a top surface of the dielectric layer. In some embodiments, the semiconductor device may also include a material layer disposed between the bottommost nanostructure of the plurality of nanostructures and the substrate, wherein a composition of the material layer is different than compositions of the plurality of nanostructures and the substrate.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a fin-shaped active region over a substrate, the fin-shaped active region comprising a plurality of channel layers interleaved by a plurality of sacrificial layers, wherein a thickness of a bottommost sacrificial layer of the plurality of sacrificial layers is greater than a thickness of a topmost sacrificial layer of the plurality of sacrificial layers;
forming a gate stack over a channel region of the fin-shaped active region;
recessing a source/drain region of the fin-shaped active region to form a source/drain opening;
replacing the plurality of sacrificial layers with a plurality of dummy layers;
epitaxially forming a source/drain feature in the source/drain opening, wherein the source/drain feature is spaced apart from the substrate by an air gap; and
replacing the gate stack and the plurality of dummy layers with a gate structure.

2. The method of claim 1, further comprising:
recessing the plurality of dummy layers to form inner spacer recesses; and
forming inner spacer features in the inner spacer recesses.

3. The method of claim 2, wherein the air gap spans a height less than a thickness of a bottommost inner spacer feature of the inner spacer features.

4. The method of claim 2, wherein a thickness of a bottommost inner spacer feature of the plurality of the inner spacer features is greater than a thickness of a topmost inner spacer feature of the plurality of the inner spacer features.

5. The method of claim 2, further comprising:
after the forming of the inner spacer features, forming an undoped semiconductor layer in the source/drain opening; and
forming a dielectric layer over the undoped semiconductor layer,
wherein the air gap is disposed between the dielectric layer and the source/drain feature.

6. The method of claim 5, wherein a top surface of the dielectric layer is lower than a top surface of a bottommost inner spacer feature of the inner spacer features.

7. The method of claim 1,
wherein the bottommost sacrificial layer comprises a first sacrificial layer and a second sacrificial layer over the first sacrificial layer, germanium concentration of the first sacrificial layer is less than germanium concentration of the second sacrificial layer, and
wherein the replacing of the plurality of sacrificial layers with the plurality of dummy layers comprises selectively removing the second sacrificial layer without fully removing the first sacrificial layer.

8. The method of claim 1, wherein the replacing of the plurality of sacrificial layers with the plurality of dummy layers comprises:
performing a first etching process to selectively removing the plurality of sacrificial layers to form a plurality of openings;
depositing a dielectric material layer over the substrate; and
performing a second etching process to etch back the dielectric material layer, thereby forming the plurality of dummy layers in the plurality of openings, respectively.

9. The method of claim 1,
wherein the bottommost sacrificial layer comprises a first sacrificial layer and a second sacrificial layer over the first sacrificial layer, germanium concentration of the first sacrificial layer is greater than germanium concentration of the second sacrificial layer, and
wherein the replacing of the plurality of sacrificial layers with the plurality of dummy layers comprises:
replacing of the first sacrificial layer with a first dummy layer; and
prior to the replacing of the first sacrificial layer with the first dummy layer, replacing of the second sacrificial layer with a second dummy layer.

10. A method, comprising:
forming a source/drain opening extending through a fin-shaped active region that comprises a plurality of channel layers interleaved by a plurality of sacrificial layers over a substrate, wherein a distance between a bottommost layer of the plurality of channel layers and the substrate is greater than a distance between two adjacent layers of the plurality of channel layers;
replacing the plurality of sacrificial layers with a plurality of dielectric layers; and
forming a source/drain feature in the source/drain opening, wherein an air gap is disposed vertically between the source/drain feature and the substrate.

11. The method of claim 10, further comprising:
recessing the plurality of dielectric layers to form inner spacer recesses; and
forming inner spacer features in the inner spacer recesses, wherein a bottommost inner spacer feature of the inner spacer features is thicker than one inner spacer feature of the inner spacer features disposed over the bottommost inner spacer feature.

12. The method of claim 11, wherein the inner spacer features comprise a topmost inner spacer feature, the bottommost inner spacer feature, and a middle inner spacer feature disposed between the bottommost inner spacer feature and topmost inner spacer feature, and a thickness of the bottommost inner spacer feature is greater than a thickness of the middle inner spacer feature and a thickness of the topmost inner spacer feature.

13. The method of claim 12, wherein the thickness of the middle inner spacer feature is equal to the thickness of the topmost inner spacer feature.

14. The method of claim 12, wherein a ratio of the thickness of the bottommost inner spacer feature to the thickness of the middle inner spacer feature is about 1.1 to about 3.

15. The method of claim 10, further comprising:
selectively removing the plurality of dielectric layers; and
forming a gate structure wrapping around the plurality of channel layers, wherein a portion of the gate structure disposed under a bottommost channel layer of the plurality of channel layers is thicker than a portion of the gate structure disposed immediately under a topmost channel layer of the plurality of channel layers.

16. The method of claim 10, further comprising:
forming an isolation layer in the source/drain opening and on the substrate,
wherein the air gap exposes the isolation layer.

17. A semiconductor device, comprising:
a plurality of nanostructures over a substrate, wherein a distance between a bottommost nanostructure of the plurality of nanostructures and the substrate is greater than a distance between two adjacent nanostructures of the plurality of nanostructures;
a source/drain feature coupled to the plurality of nanostructures;
an air gap disposed vertically between the source/drain feature and the substrate; and
a gate structure wrapping around and over each of the plurality of nanostructures.

18. The semiconductor device of claim 17, further comprising:
a plurality of inner spacer features disposed between the gate structure and the source/drain feature, wherein a bottommost inner spacer feature of the plurality of inner spacer features is thicker than other inner spacer features of the plurality of the inner spacer features.

19. The semiconductor device of claim 18, further comprising:
a dielectric layer adjacent to the bottommost inner spacer feature, wherein the air gap exposes a top surface of the dielectric layer.

20. The semiconductor device of claim 18, further comprising:
a material layer disposed between the bottommost nanostructure of the plurality of nanostructures and the substrate, wherein a composition of the material layer is different than compositions of the plurality of nanostructures and the substrate.
